(19) United States
(12) Patent Application Publication
(10) Pub. No.: US 2017/0310207 A1
(43) Pub. Date: Oct. 26, 2017

(54) CIRCUIT FOR ALLEVIATING HIGH FREQUENCY SWITCHING NOISE AND VOLTAGE OVERSHOOTING IN SEMICONDUCTOR COMPONENTS ARRAYS AND RETURNING ENERGY THEREFROM

(71) Applicant: Silicon Power Corporation, Clifton Park, NY (US)

(72) Inventors: JAMES K. AZOTEA, Saratoga Springs, NY (US); John E. Waldron, Clifton Park, NY (US)

(21) Appl. No.: 15/139,031

(22) Filed: Apr. 26, 2016

(51) Int. Cl. H02M 1/34; H01L 29/872; H01L 29/808; H02M 7/217; H01L 29/16

(52) U.S. Cl. CPC H02M 1/34; H02M 7/217; H01L 29/1608; H01L 29/808; H01L 29/872

(57) ABSTRACT

A circuit for transferring parasitic energy to an external load. The circuit includes a first array of semiconductor switches connected in parallel with one another, a second array of semiconductor switches connected in parallel with one another, an external load connected in parallel with the second array of semiconductor switches, an extended-time saturable reactor (ETSR), and a voltage snubber capacitor. The second array of semiconductor switches is connected in series with the first array of semiconductor switches. The ETSR is connected in series with the second array of semiconductor switches. The voltage snubber capacitor is connected in parallel with the second array of semiconductor switches and the ETSR. The circuit may further include an energy return circuit including an isolation transformer for returning energy in the voltage snubber capacitor to the external load. The external load can include a capacitive load or an external power supply.

### FIELD OF THE INVENTION

The invention relates to circuits for semiconductor components array and, more specifically, to a circuit comprising one or more semiconductor component arrays, an extended-time saturable reactor, and a polarized voltage snubber for alleviating high frequency switching noise in the one or more semiconductor component arrays and voltage overshoot and for returning energy captured by the polarized voltage snubber to a load or to an external power supply.

### BACKGROUND OF THE INVENTION

As the modular advanced power semiconductor switch industry realizes greater power densities, it becomes harder for the power conversion engineer to manage the greater parasitic elements of the paralleled components in densely packed power device arrays. This is especially a problem at the fast switching speeds of these components, which are being used in energy conversion topologies.

Semiconductor components, such as silicon carbide (SiC) Schottky diodes and SiC JFET power switch device arrays, are now being implemented in power modules to reduce the switching and the conduction losses to increase both the efficiency and the power density of the power modules. The connection of parasitic semiconductor resistances, capacitances, and wiring inductances in such power modules can easily create severely under damped switching conditions. Extreme oscillations are inevitable when the semiconductor devices that are forward blocking at high voltage are gated “ON” and “OFF”. SiC JFETs have lower switch resistances, a higher device capacitance, a finite wiring inductance built into their geometry and have a low turn-on gate threshold. Parasitic capacitive energy is initially stored in the JFETs and their associated anti-parallel SiC diode arrays when a bus voltage is applied to them.

Power converter control systems often “blank” or ignore turn-on current spikes, but a large amplitude of ringing can cause the control system to malfunction and turn on power switches even though they are gated off. Unintentionally turning-on power switches can have disastrous consequences. High-frequency switching noise, for example transient voltages and currents may affect control circuitry and falsely trigger these power converter control system. A circuit that that can mitigate instantaneous current spikes and reduce amplitude ringing from the parasitic energy in the circuit while using the parasitic energy to power loads and voltage sources may be beneficial to the Art.

### SUMMARY OF THE INVENTION

In accordance with an aspect of the invention, an electrical circuit is provided that may capture, use, or store the potentially wasted energy stored in the parasitic elements of semiconductor component arrays and wiring inductance internal to a high-power density power module. At the same time, the circuit provides voltage protection to sensitive semiconductor components and mitigates high frequency switching noise (transient voltages and currents) that may affect control circuitry and false trigger semiconductor switches in the module. The circuit is electrically isolated to electrically reference electrical energy to various power sources, control circuitry, and loads. The circuit also improves EMI emissions and increases efficiency.

### BRIEF DESCRIPTION OF THE FIGURES

FIG. 1 is a general block diagram of a high power density power module in accordance with an embodiment of the invention;

FIG. 2 is a circuit topology of a high power density power module in accordance with an embodiment of the invention;

FIG. 2A is a circuit topology as a model of the high power density power module of FIG. 2 in accordance with an embodiment of the invention;

FIG. 3 is a timing diagram that illustrates voltage and current characteristics of a power switch device array (PSDA), without countermeasures, in accordance with an embodiment of the invention;

FIG. 4 is a schematic of an extended time saturable reactor (ETSR) PSPICE model test circuit according to an embodiment of the invention;

FIG. 5 is a timing diagram that verifies the volt-seconds capability of the ETSR PSPICE model according to an embodiment of the invention;

FIG. 6 is a timing diagram that illustrates voltage and current characteristics of a PSDA with the use of a ETSR according to an embodiment of the invention;

FIG. 7 is a timing diagram that illustrates voltage and current characteristics of a PSDA with the use of a voltage snubber capacitor without an ETSR according to an embodiment of the invention;

FIG. 8 is a timing diagram that illustrates voltage and current characteristics of a PSDA with the use of a ETSR and a voltage snubber capacitor according to an embodiment of the invention;

FIG. 9 is a timing diagram that illustrates high frequency switching noise without ETSR and a voltage snubber capacitor according to an embodiment of the invention;

FIG. 10 is a timing diagram that illustrates the absence of high frequency switching noise with an ETSR and a voltage snubber capacitor according to an embodiment of the invention;

FIG. 11A is a linear transformer-forward converter circuit topology diagram of an energy return circuit in accordance with an embodiment of the invention;

FIG. 11B is a flyback-converter circuit topology with an external switch control circuitry diagram for an energy return circuit in accordance with an embodiment of the invention;

FIG. 11C is a diagram of a linear transformer-forward converter circuit topology configured to return capacitor snubber energy in accordance with an embodiment of the invention;

FIG. 12 is an equivalent electrical model schematic circuit diagram for an linear transformer-forward converter for an energy return circuit of FIG. 11A, in accordance with an embodiment of the invention;

FIGS. 13A-D illustrate identical timing diagrams for simulations of power converter and energy return circuit in accordance with an embodiment of the invention;

FIG. 14 illustrates functioning timing diagrams for resonant discharge in an energy return circuit (FIG. 11B) in accordance with an embodiment of the invention;

FIG. 15 illustrates voltage and current characteristics for a snubber capacitor in accordance with an embodiment of the invention;

### DETAILED DESCRIPTION OF THE INVENTION

In describing embodiments of the invention illustrated herein and in the drawings, specific terminology will be resorted to for the sake of clarity. However, the invention is not intended to be limited to the specific terms so selected, and it is to be understood that each specific term includes all technical equivalents that operate in similar manner to accomplish a similar purpose. Several preferred embodiments of the invention are described for illustrative purposes, it being understood that the invention may be embodied in other forms not specifically shown in the drawings.

In accordance with an embodiment of the invention, a high-power-density power module (HPDPM) circuit may be used for switching an inductive load connected to HPDPM circuit. The HPDPM may store the parasitic energy from the semiconductors, module wiring, and “Snubber” components and transfer the parasitic energy back to a load or an energy source with extremely high efficiency, reduces total part cost, volume, thermal management requirements for the HPDPM. The HPDPM circuit may also provide voltage protection to sensitive semiconductor components and mitigate the high frequency switching noise (transient voltages and currents) that may affect the control circuitry and false trigger one or more power switch device arrays in the HPDPM.

In accordance with another embodiment of the invention, the HPDPM circuit may comprise one or more array of semiconductor switches, an extended-time saturable reactor (ETSR), a polarized voltage snubber (PVS), and forward and/or flyback converters. One or both of the ETSR and PVS may be used for alleviating high frequency switching noise and voltage overshoot in densely populated semiconductor component arrays located within the HPDPM.

In accordance with an embodiment of the invention, a Forward or Flyback power converter may be configured from or with the HPDPM for transferring energy from the PVS of the HPDPM circuit to a load or a source of power. In one embodiment, the power converter may comprise an isolation transformer comprising a pair of primary windings and a pair of secondary windings. The pair of primary windings may be connected in parallel to reduce conduction losses and are connected to the VSC in parallel through a semiconductor switch array is in an “ON” state. The pair of secondary windings may be connected in series to raise the transformer output voltage higher than the power supply voltage to transfer load current. The internal module power converter may be comprised of one or both an inductor and/or transformer leakage inductance and a rectifier diode in series with one another and with the secondary windings of the isolation transformer. The isolation transformer transfers energy from the VSC of the PVS, through the transformer leakage inductance and or externally added inductances and rectifier diode to an external load. In this way, parasitic energy of the high-power-density power circuit may be captured, transferred, limited, and/or used and not wasted.

In another embodiment, the Flyback topology power converter control circuitry may be comprised of a monostable multivibrator, a NOR gate latch, an opto-coupler with a series blocking diode, a gate drive current amplifier, and a semiconductor switch. The output of the gate drive current amplifier may be connected to the gates of additional semiconductor switches of the Flyback topology energy return circuit. The rising edge of the semiconductor switch array gate driver triggers the output of the monostable multivibrator to “SET” the output of the NOR gate latch. This drives the gate drive current amplifier, which turns on the additional Flyback power switch transferring the capacitor snubber energy to the primary of the transformer. The NOR latch is gated “OFF” when the snubber cap voltage is near or at zero volts. The Flyback energy return power converter further comprises a transformer comprising a primary winding and a secondary winding. The primary winding is connected in series with the additional semiconductor switch. The series primary winding/semiconductor switch is connected in series with the VSC of the high-power-density power circuit. The second winding of the transformer is connected in series to a steering diode and to a power source or load. The energy stored in the primary of the Flyback transformer is transferred to the transformer secondary, through the steering diode, to the power supply or loads when the NOR gate latch is gate “OFF”.

In an embodiment, the ETSR may insert a significant amount of inductive impedance in series with the power switch arrays for a specified volt-time duration during turn-on (T_{ON}). Such inductance increases the characteristic impedance of the circuit to limit the amplitude of the T_{ON} current and limits the instantaneous rate of current change, dI/dt, to reduce the ringing in the T_{ON} current waveform.

A low or zero value of inductance is preferred in the module when the module is fully switched on. To that end, the ETSR inductance is initially high for a predetermined volt-seconds and reduces to a minimum inductance (leakage inductance) after exceeding a given amount of volt-seconds. The value of minimum inductance is determined by the permeability of free space, the number of turns used, and the core geometry. Adding a significant amount of inductance in series with the semiconductor component arrays during switch turn-off (T_{OFF}) at near the zero-current crossing limits the dI/dt of the switch current which reduces current ringing that causes voltage overshoot. To that end, the ETSR resets at near zero-current crossing and provides a significant amount of inductive impedance during T_{OFF}.

The residual energy stored in the ETSR air core inductance and parasitic wiring inductance during turn-off (T_{OFF}), may be captured by the PVS where it is stored. The energy captured by the PVS may be recovered and transferred to loads or back to an energy source for use at the beginning of each switch turn-on (T_{ON}) cycle with extremely high efficiency

In accordance with an embodiment of the invention, the parasitic energy stored in the semiconductors, module wiring, and snubber components of the PVS within the HPDPM may be recovered and transferred back to a load or energy source with extremely high-efficiency which reduces total part cost, volume, thermal management requirements for the PVS and reduces electromagnetic interference (EMI). The module also reduces ringing in voltage overshoot and turn-on current spikes in the semiconductor component arrays. Such reduction in ringing greatly reduces electro-magnetic interference (EMI) both conducted and radiated into the module.

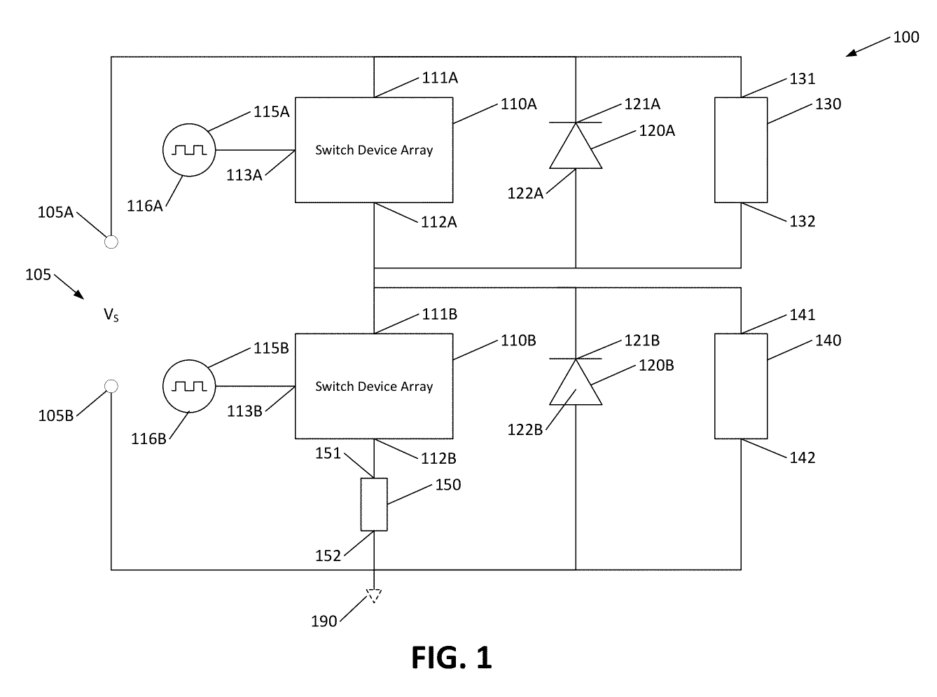

Referring now to FIG. 1, there is illustrated an exemplary circuit, generally designated as 100, that may be used for reducing excessive voltage transients and high-frequency noise during switching one or more switch arrays, in accordance with an embodiment of the invention. In an embodiment, the circuit 100 may be a high power-density power-module (HPDPM) that includes a plurality of power switch device arrays 110A, 110B that are arranged in half-bridge (H-bridge) configurations that may be used for switching input power to an inductive load.

The circuit 100 comprises a voltage input 105 comprising a high voltage input terminal 105A and a low voltage input terminal 105B. The voltage input 105 may be coupled to a voltage source (not illustrated). The circuit 100 further comprises a first switch device array 110A, a second switch device array 110B, a first diode array 120A, a second diode array 120B and inductive load 130. The first switch device array 110A is connected in parallel across the diode array 120A and the second switch device array 110B is connected in parallel with the second diode array 120B. The first switch device array 110A comprises an input 111A, an output 112A, and a gate 113A. The second switch device array 110B comprises an input 111B, an output 112B, and a gate 113B. The input 111A of the first switch device array 110A is coupled to the high voltage input terminal 105A. The output 112A of the first switch device array 110A is coupled to the input 111B of the second switch device array 110B. The first and the second diode-switch arrays 110A-110B may be selectively controlled to transmit power from the voltage input 105 to the inductive loads 130 with respect to input 105B.

The circuit 100 comprises an inductive load 130. The inductive load 130 comprises a first end 131 and a second end 132. The cathode 121A of the first diode array 120A and the first end 131 of the inductive load 130 are coupled to the high voltage input 105A. The cathode 121A of the first diode array 120A and the first end 131 of the inductive load 130 are coupled to the high voltage input 105A. The anode 122A of the first diode array 120A and the second end 132 of the inductive load 130 are coupled to the input 111B of the second switch device array 110B.

The circuit further comprises a voltage snubber 140 and a saturable reactor 150. The saturable reactor may be an extended time saturable reactor (ETSR), which has a variable inductance over time. An example of a saturable reactor that may be used is an AMOBEAD manufactured by Toshiba corporation (AMOBEADS is a Registered trademark of Toshiba; Toshiba is a registered trademark). The second diode array 120B comprises a cathode 121B and an anode 122B. The voltage snubber 140 comprises a first end 141 and a second end 142. The saturable reactor 150 comprises a first end 151 and a second end 152. The cathode 121B of the second diode array 120B and the first end 141 of the voltage snubber 140 are coupled to the input 111B of the second switch device array 110B. The anode 122B of the second diode array 120B and the second end 142 of the voltage snubber 140 are coupled to the output 152 of the saturable reactor 150. The input 151 of the saturable reactor 150 is coupled to the output 112B of the second switch device array 110B. The output 152 of the saturable reactor 150 is coupled to the low voltage input 105B. In an exemplary embodiment, the output 152 of the saturable reactor 150 is also coupled to ground 190.

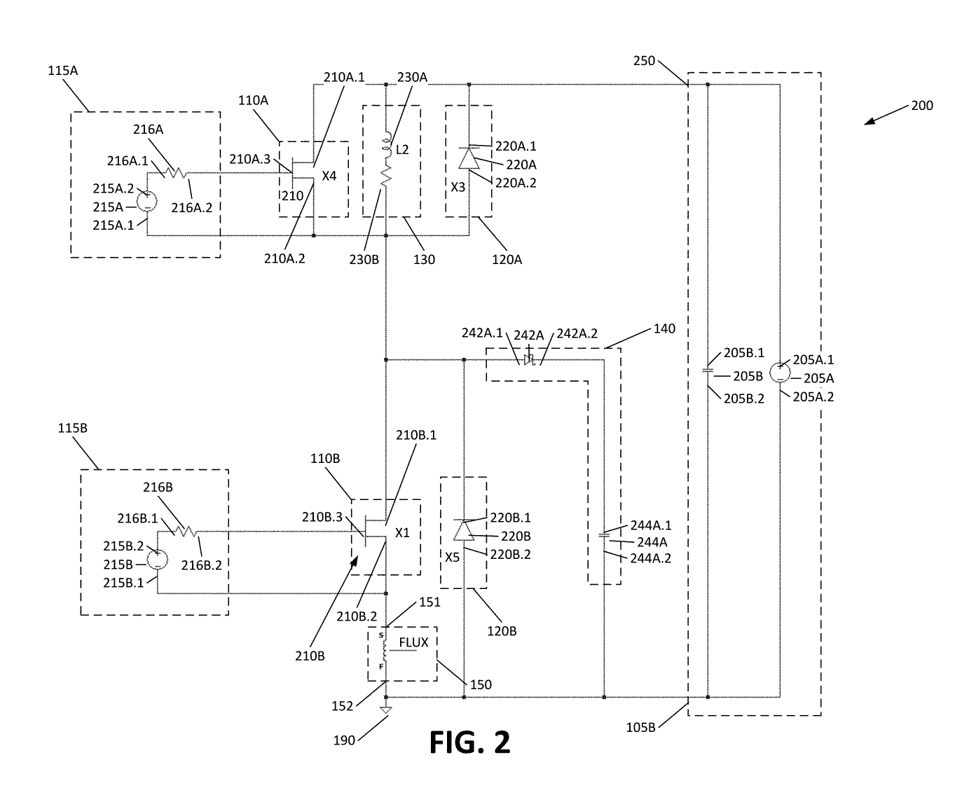

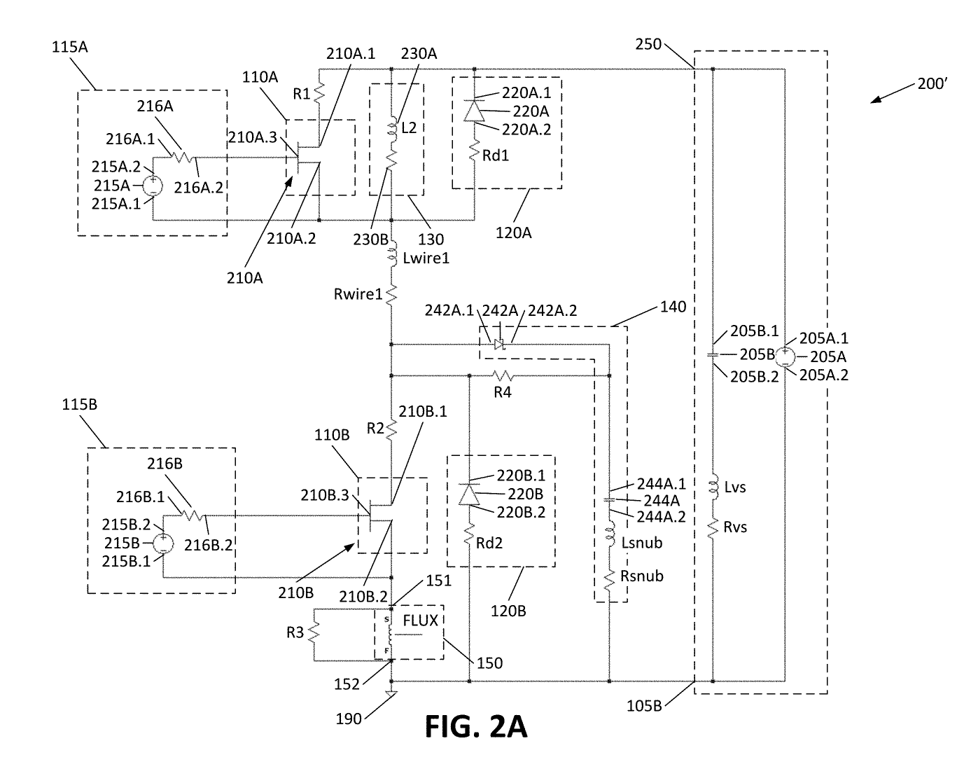

Coupled to the gate 113A of the first switch device array 110A is a first gate driver 115A. Coupled to the gate 113B of the second switch device array 110B is a second gate driver 115B. The first gate driver 115A provides control signals 116A to the gate 113A, with respect to output 112A, of the first switch device array 110A to command the first switch device array 110A to open or close. The second gate driver 115B provides control signals 116B to the gate 113B, with respect to 112B, of the second switch device array 110B to command the second switch device array 110B to open or close. Operation of the HPDPM circuit 100 is described in detail in the embodiment of FIG. 2.

Illustrated in FIG. 2 is an embodiment of the circuit 100, generally designated as 200 in FIG. 2, in accordance with an exemplary embodiment of the invention. The circuit 200 illustrates exemplary components for each element of the circuit 100. In the circuit 200, the gate driver 115A comprises a voltage source 215A and a source resistance 216A. The voltage source 215A comprises a first terminal 215A.1 and a second terminal 215A.2, and the source resistance 216A comprises a first end 216A.1 and a second end 216A.2. The source resistance 216A is in series with the voltage source 215A such that the second terminal 215A.2 of the voltage source 215A is connected to the first end 216A.1 of the source resistance 216A. The gate driver 115B comprises a voltage source 215B and a source resistance 216B. The voltage source 215B comprises a first terminal 215B.1 and a second terminal 215B.2, and the source resistance 216B comprises a first end 216B.1 and a second end 216B.2. The source resistance 216B is in series with the voltage source 215B such that the second terminal 215B.2 of the voltage source 215B is connected to the first end 216B.1 of the source resistance 216B.

The first switch device array 110A comprises a plurality of solid-state switches 210A in parallel with one another, and the second switch device array 110B comprises a plurality of solid-state switches 210B in parallel with one another. Each solid-state switch 210A comprises an input 210A.1, an output 210A.2, and a gate 210A.3. The gates 210A.3 of the solid-state switches 210A are coupled to the second end 216A.2 of the source resistance 216A. The outputs 210A.2 of the solid-state switches 210A are coupled to the first terminal 215A.1 of the voltage source 215A. Each solid-state switch 210B comprises an input 210B.1, an output 210B.2, and a gate 210B.3. The gates 210B.3 of the solid-state switches 210B are coupled to the second end 216B.2 of the source resistance 216B. The outputs 210B.2 of the solid-state switches 210B are coupled to the first terminal 215B.1 of the voltage source 215B. In an exemplary embodiment, the solid-state switches 210 are Enhancement Mode (EM) Silicon Carbide (SiC) Junction Field Effect transistors (JFETs). In such embodiment, the circuit 200 is a high power density power module (HPDPM) in a half-bridge (H-bridge) configuration switching the inductive load 130.

In the circuit 200, the load 130 is an inductive load comprising an inductor 230A and a resistor 230B connected in series. The series inductor 230A and resistor 230B are connected in parallel with the plurality of solid-state switches 210A. Thus, a first end of the inductor 230A is connected to the inputs 230A.1 of the plurality of solid-state switches 210A, and a second end of the resistor 230B is connected to the outputs 230A.2 of the plurality of solid-state switches 210A. It is to be understood that the inductive load is represented as the series inductor 230A and resistor 230B and that it relevant exemplary embodiment may comprise any components that are inductive and resistive.

The first diode array 120A comprises a plurality of diodes 220A connected in parallel with one another and in parallel with the plurality of solid-state switches 210A and the load 130. The cathodes 220A.1 of the diodes 220A are connected to the inputs 210A.1 of the solid-state switches 210A, and the anodes 220A.2 of the diodes 220A are connected to the outputs 210A.2 of the solid-state switches 210A. In an exemplary embodiment in which the plurality of solid-state switches 210A comprises metal-oxide-semiconductor field-effect transistors (MOSFETs), the plurality of diodes 220A comprises intrinsic body diodes of the MOSFETs and are, therefore, part of the same circuit components as the MOSFETs. If EM SiC JFET's are used in lieu of MOSFETS, then a diode array 120A may also be used. The diode array 120A may comprise discrete SiC diodes.

The second diode array 120B comprises a plurality of diodes 220B connected in parallel. The cathodes 220B.1 of the diodes 220B are connected to the inputs 210B.1 of the solid-state switches 210B, and the anodes 220B.2 of the diodes 220B are connected to the second end 152 of the saturable reactor 150. The first end 151 of the saturable reactor 150 is connected to the outputs 210B.2 of the solid-state switches 210B. In an exemplary embodiment in which the plurality of solid-state switches 220B comprises MOSFETs, the plurality of diodes 220B comprises intrinsic body diodes of the MOSFETs and are, therefore, part of the same circuit components as the MOSFETs. (The diode array 120B is comprised of discrete SiC diodes if using Enhancement Mode (EM) SiC JFETs. There are no intrinsic body diodes in an EM SiC JFET. Please add this claim)

The voltage snubber 140 comprises a diode 242A in series with a capacitor 244A. The anode 242A.1 of the diode 242A is connected to the outputs 210A.2 of the solid-state switch arrays 210A and to the inputs 210B.1 of the solid-state switch arrays 210B. The capacitor 244A comprises a first end 244A.1 and a second end 244A.2. The first end 244A.1 of the capacitor 244A is connected to the cathode 242A.2 of the diode 242A. The second end 244A.2 of the capacitor 244A is connected to the anodes 220B.2 of the diodes 220B and to the second end 152 of the saturable reactor 150.

The voltage input 105 comprises a voltage source 205A and a capacitor 205B connected in parallel and between the high voltage input 105A and the low voltage input 105B. The voltage source 205A comprises a first terminal 205A.1 and a second terminal 205A.2. The capacitor 205B comprises a first end 205B.1 and a second end 205B.2. The first end 205B.1 is connected to the first terminal 205A.1 of the voltage source 205A, and the second end 205B.2 is connected to the second terminal 205A.2 of the voltage source 205A. The first terminal 205A.1 of the voltage source 205A is connected to the inputs 210A.1 of the solid-state switches 210A, and the second terminal 205A.2 of the voltage source 205A is connected to the outputs 210A.2 of the solid-state switches 210A.

The saturable reactor 150 has a high initial inductive impedance to limit capacitive current spikes during T_{ON} switching. This is accomplished by designing a saturable reactor with an extended volts-second product (herein “V-S”) and placing the extended-time saturable reactor (ETSR) 150 in the most effective series noise reduction path. In the exemplary circuit 200 illustrated in FIG. 2, this path is the series connection with the outputs 210B.2 of the plurality of solid-state switches 210B. 1).

After exceeding the V-S during T_{ON}, the reactor 150 saturates or changes to a low inductive impedance. The reactor 150 returns to a high inductive impedance when the current through the reactor 150 is near or at zero current level, e.g. after T_{OFF} of the saturable reactor 150. The increase in inductance at “zero current crossing” limits the dI/dt, as inductors resist changes in current, to suppress the parasitic component ringing when the circuit 200 turns off the plurality of solid-state switches 210B to turn-off the current through the load 130. The V-S product of the ETSR 150 must be increased (extended) to limit the peak circuit current into a parasitic capacitance (Cp) as the lower switch 210B turns on. The parasitic capacitance (Cp) is a combined capacitance of the switch arrays 110A and diode arrays 220A. The ETSR limits or controls the flow of parasitic energy through the circuit and limits the T_{ON} current spike at low voltage (maximum capacitance) when switch array 210B turns ON into the upper parasitic capacitance from switch arrays 110A and diode arrays 220A.

The voltage snubber 140, specifically the voltage snubbing capacitor (“VSC”) 244A, is used to capture the parasitic-inductive energy stored in the saturable reactor 150 when the plurality of solid-state switches 210B turn off. As described below, the inductive energy from the reactor 150, which was transferred to the VSC 244A, is transferred through a linear isolation transformer such as, for example, a forward converter or a coupled inductor using a fly-back converter, to an energy storage area or a load when the plurality of solid-state switches 210B turn on. In another exemplary embodiment, a forward converted is used to transfer such energy. In an exemplary embodiment, the inductive energy capture to the VSC 244A is transferred back to the capacitor 205B.

Illustrated in FIG. 2A is a model of the circuit 200, which model is generally designated as 200′, in accordance with an exemplary embodiment of the invention. The circuit model 200′ is specifically a PSPICE simulation of the circuit 200. The circuit model 200′ comprises all of the components of the circuit 200, with specific values, and further comprises several components representing parasitics of the circuit 200. Thus, the circuit model 200′ is a model of an implementation of the circuit 200.

The plurality of solid-state switches 210A comprises 10 (ten) EM SiC JFETs in parallel, and the plurality of Schottky diodes 220A comprises 8 SiC Schottky diodes in parallel representing the discrete diodes of the 10 EM SiC JFETs. The plurality of solid-state switches 210B comprises 10 (ten) EM SiC JFETs in parallel, and the plurality of Schottky diodes 220B comprises 8 silicon carbide (SiC) Schottky diodes in parallel representing the discrete body diodes of the 10 (ten) EM SiC JFETs. The EM SiC JFETs 210A parallel with the Schottky diodes 220A represents a single low resistance from drain-source (R_{DSon}) MOSFET with fast reverse recovery diodes connected reverse bias across the drain 210A.2 to source 210A.1. The EM SiC JFETs 210B parallel with the Schottky diodes 220B represents a single low R_{DSon} EM SiC JFETs with fast reverse recovery diodes connected reverse bias across the drain 210B.2 to source 210B.1. In an embodiment, the HPDPM circuit may include EM SiC JFETs and SiC Schottky diodes to represent sub-circuits 210A and 210B. In another embodiment, silicon MOSFETs (i.e., EM MOSFETs with their intrinsic diodes), EM MOSFETS with parallel silicon Schottky diodes or Fast Recovery Epitaxial Diodes FRED), may be used to represent sub-circuits 210A and 210B. The parasitics in the circuit model 200′ model the resistances and inductances of the wires or traces of the circuit 200 and the internal resistances of the components of the circuit 200. The wiring resistance is modeled as a resistor R1 is connected in series with the Power Switches 210A, specifically in series with the drains 210A.1 of the Power Switches 210A. The wiring resistance is modeled as a resistor Rd1 connected in series with the diodes 220A, specifically in series with the anodes 220A.2 of the diodes 220A. The wiring resistance is modeled as a resistor R2 connected in series with the Power Switches 210B, specifically in series with the drains 210B.1 of the Power Switches 210B. The wiring resistance is modeled as a resistor Rd2 connected in series with the diodes 220B, specifically in series with the anodes 220B.2 of the diodes 220B Power Switches that may include EM SiC JFETs. The series resistance of all the power devices that are modeled may be nested inside a PSPICE model where all resistances may be modeled from wiring the devices together electrically.

The resistance of the wires or traces connecting the Power Devices 210A and 220B together is modeled as a resistance Rwire1 and the inductance of such connection is modeled as an inductor Lwire1. Rwire1 and Lwire1 are modeled in series and as connecting the sources 210A.2 of the Power Devices 210A with the drains 210B.1 of the Power Devices 210B.

The core loss of the saturable reactor 150 is modeled as a resistance R3 in parallel with the saturable reactor 150. The Estimated Series Resistance (ESR) of the snubber capacitor 244A and the resistance of the wires or traces of the voltage snubber 140 and its connections is modeled by a resistor Rsnub. The Estimated Series Inductance (ESL) of the snubber capacitor, wires or traces of the voltage snubber 140 and its connections is modeled by an inductor Lsnub. The ESR and ESL of the input capacitor 205B and wiring resistance and wiring inductance, are modeled as a resistance Rvs and an inductance Lvs in series with one another and with the capacitor 205B.

Finally, the circuit model 200′ further comprises a resistor R4 in parallel with the diode 242A. The resistor R4 is included in the circuit model 200′ to discharge the capacitor 244A when the switches 210B are turned ON. It is to be understood that the resistor R4 is included in the circuit model 200′ for testing purposes only. It is not used in the circuit 200 because the energy stored in the capacitor 244A is returned to the source 105 in the circuit 200.

The values of the various simulated components in the circuit model 200′ may be as follows, where Ω are ohms and H are Henry's:

TABLE 1
Value of components used in the simulation
of the circuit model 200′

| Component | Value | |
|---|---|---|
| Resistor 216A | 0.1 | Ω |
| Resistor R1 | 500 | μΩ |
| Inductor 230A | 40 | μH |
| Resistor 230B | 1 | mΩ |
| Resistor Rd1 | 1 | mΩ |
| Inductor Lwire1 | 50 | nH |
| Resistor Rwire1 | 1 | mΩ |
| Resistor 216B | 0.1 | Ω |
| Resistor R2 | 1 | mΩ |
| Resistor Rd2 | 1 | mΩ |
| Resistor R3 | 10 | kΩ |
| Lsnub | 1 | nH |
| Rsnub | 10 | mΩ |
| Inductor Lvs | 10 | nH |
| Resistor Rvs | 10 | mΩ |
| Resistor R4 | 10 | Ω |

An equivalent parallel capacitance of the switches 210A and 220A in the circuits 200 and 200′ can be quite large at 0V or when the plurality of Schottky diodes 220A are forward biased. The equivalent RDSON and wiring inductance is very low. An example MOSFET used can be 1200V/25 A power MOSFET (for example, an IXKC25N80C N-channel MOSFET) with an Rdson=0.15Ω. An equivalent Rdson, for ten MOSFETs wired in a parallel circuit configuration, would be equal to 0.015Ω. The effective capacitance of the components 210A, 220A, 210B, and 220B may be calculated by entering the simulated peak current, estimated Rdson, estimated wiring inductance, and applied bus voltage into Equation (2) below.

$$\begin{matrix}{I}_{p} = ( ( Vin ) ) / ( ( Rdson + √ ( Lp / Cp ) ) = ( ( 600 V ) ) / ( ( 0.015 Ω + 50 nH / Cp ) ) = 250 A & ( 1 ) \\ Cp = \frac{( Lp )}{( ( \frac{Vin}{Ip} ) - Rdson ) \text{?}} = \frac{( 50 n )}{( ( 250 A ) - 0.015 Ω ) \text{?}} = 8.79 nF & ( 2 ) \\ Rd = 2 √ \frac{Lwire 1}{( Cp )} = 2 √ \frac{50 nH}{( \text{?} .79 pF )} = 2 ( 2.385 ) = 4.77 Ω , \\ \text{?} \text{indicates text missing or illegible when filed} & ( 3 )\end{matrix}$$

### Let: Ip=250 A, Vin=600V, Lwire1=50 nH, Rdson=0.015Ω

Where: Ip=Peak amplitude of the TURNON transient current
Vin=Applied bus voltage
Lp=Parasitic wiring inductance Lwire1
Cp=Diode 220A and MOSFET 210A array capacitance
Rd=Series damping resistance

Calculating the critical damping resistance, using Cp and Lwire1, shows the value of series resistance needed to switch the series circuit (switches 210A and 210B) without oscillation. Equation (4) below shows the MOSFET resistance is two orders of magnitude smaller than the resistance needed to damp the parasitic capacitance of the switches 210A and 210B and diodes 220A and 220B and wiring inductance (Lp).

Rd/Rdson=4.77 Ω/0.015 Ω=318 (4)

The Schottky diodes 220A and 220B does not have a significant recovery time. There is no charge carrier depletion region at the junction in the diodes 220A and 220B, but switching into the maximum parasitic capacitance of many parallel MOSFETs 210A, 210B can cause high peak currents and generate horrific Electro-magnetic Interference (EMI).

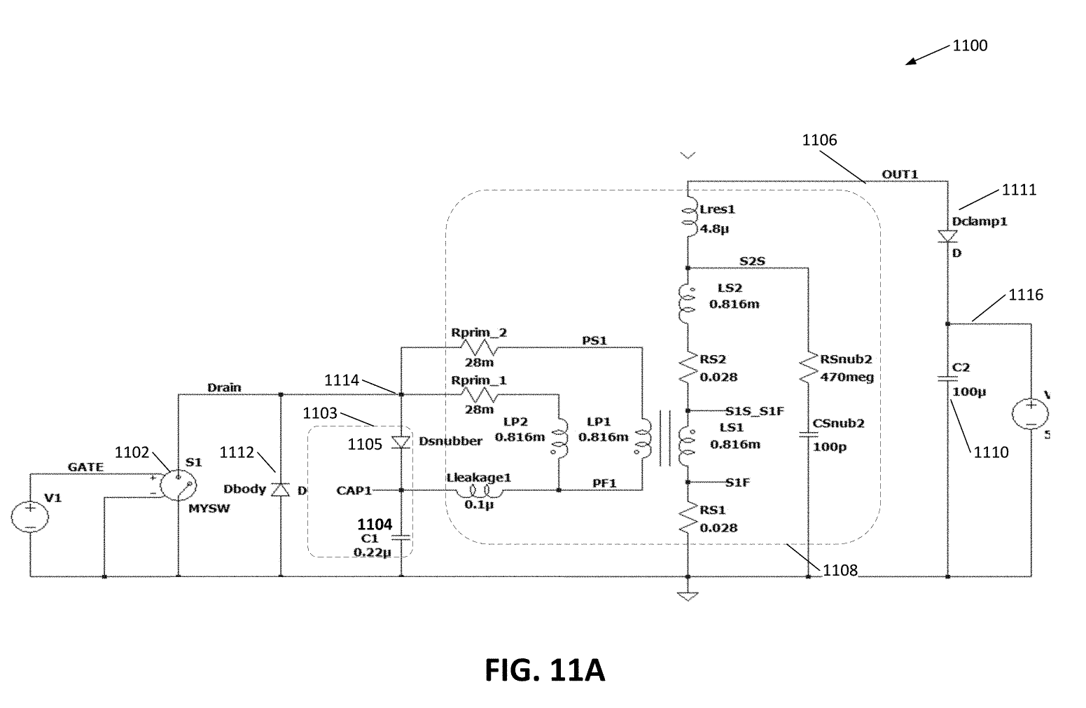

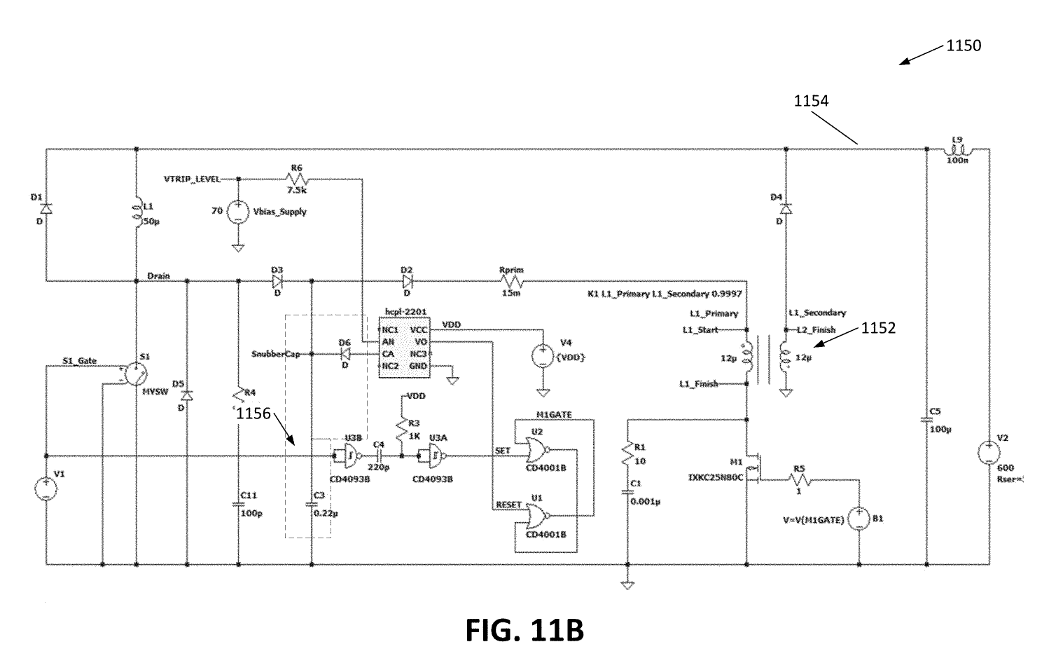

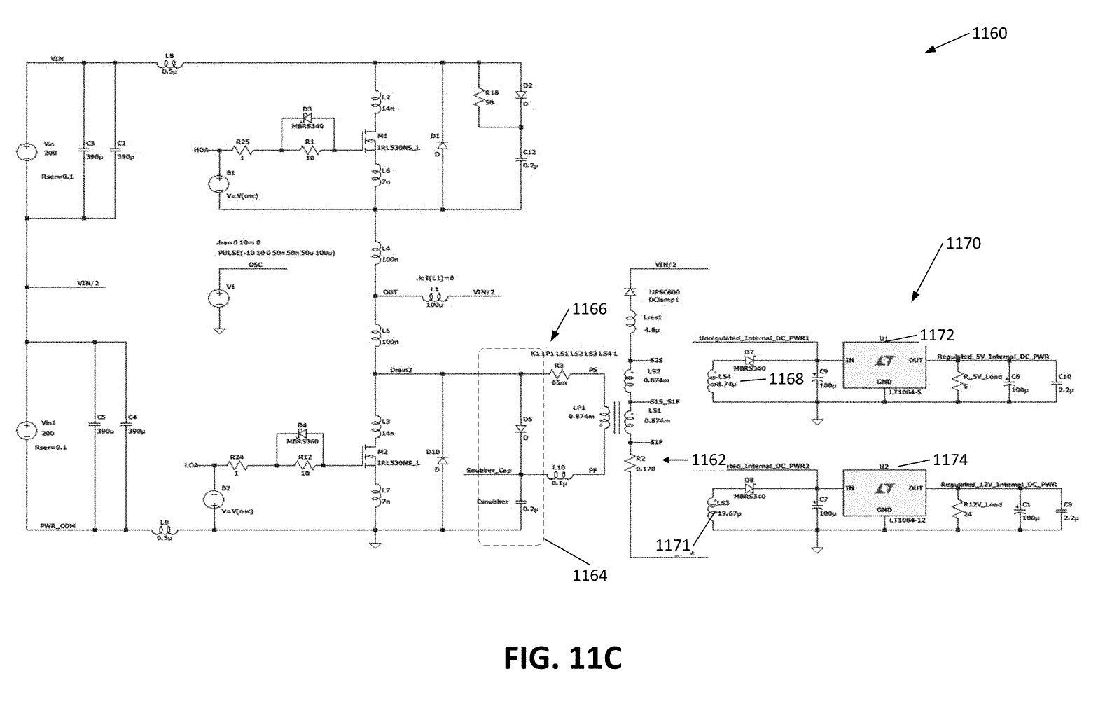

In operation, the PVS 140 may be used to absorb the energy of the wiring inductance when an inductive load current is being turned off. The snubber capacitor VSC 244A may be charged to the rail voltage 250 plus an inductive voltage overshoot generated from the wiring inductance. The capacitor VSC 244A may discharge through resistor R4 when lower switch 210B turns ON (acts as a forward converter) and resets the snubber capacitor VSC 244A. The power dissipated in the resistor R4 may be the energy stored in the capacitor VSC 244A timed the frequency of operation. In an example, the power dissipated in the resistor R4 is 34.57 mJ×20 KHz=491 Watt. The power dissipated may be returned to the system to power loads or external power sources in lieu of wasted power, for example, wasted power in conventional circuits, as will be described using the power converter circuits 1100 of FIG. 11A or 1150 of FIG. 11B.

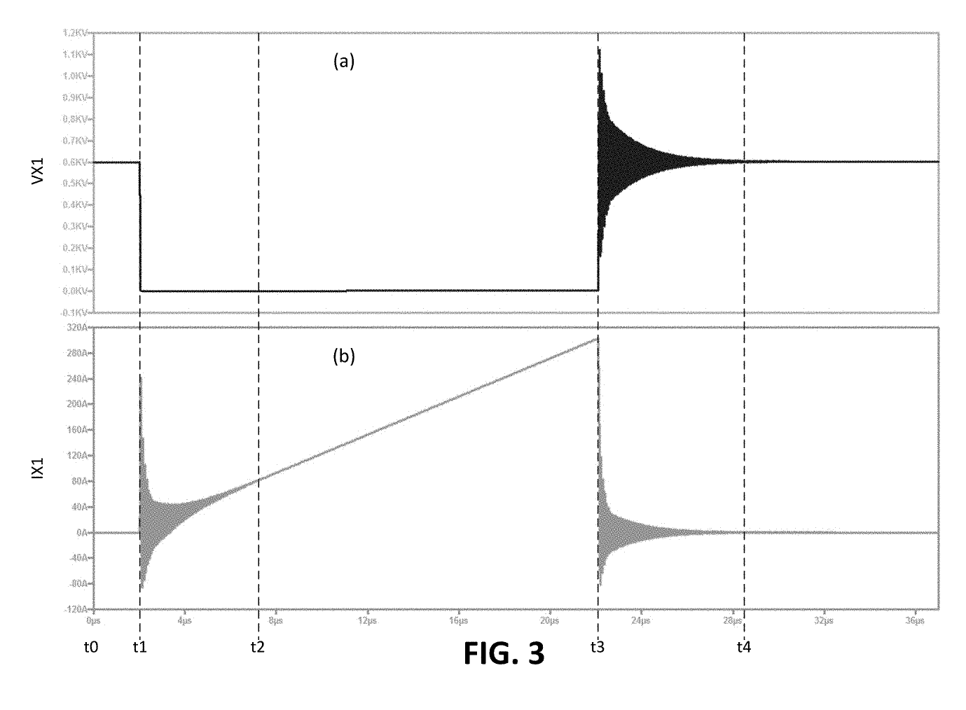

Referring now to FIG. 3 are voltage and current waveforms for a non-limiting illustrative embodiment of the circuit 200 in which the voltage snubber 140 and the saturable reactor 150 have been removed from the circuit 200, in accordance with an exemplary embodiment of the invention. Specifically, voltage and current waveforms for the switches 210B are shown without the use of the saturable reactor 150 or the voltage snubber 140 in the circuit 200. Between t0 and t1, e.g. between 0 seconds and 2 μseconds (μs), the switches 210B are off and, therefore, not conducting. Thus, the voltage across the switches 210B is equal to Vs, e.g. 600V and the current through the switches 210B is 0 A between t0 and t1.

At time t1, the switches 210B are turned on and the voltage decreases to the voltage drop across the switches 210B. The current spikes, e.g. to 240A, and rings excessively at turn-on (T_{ON}). Specifically, the current spikes above and then below the zero current reference (ground potential) and oscillates or rings between +/−. The voltage across the switches 210B does not ring at T_{ON}. After t1, the voltage remains substantially constant and the current increases linearly, while the excessive ringing in the current eventually subsides by time t2, e.g. 7 μs. The current increases linearly at the slope of Vin/L2 to a peak value of 300 A at time t3, e.g. 22 μs.

At time t3, e.g. 22 μs, the switches 210B are turned off and the voltage across the switches 210B spikes, e.g. to 1.2 kV, and rings excessively thereafter. At time t3 the current through the switches 210B spikes down, e.g. to −80 A and rings thereafter above and below the zero current reference. In the exemplary embodiment shown, the switches 210B see 500V of voltage overshoot and high frequency ringing caused by the high dI/dt during T_{OFF} at zero crossing, parasitic capacitance (Cp), and parasitic wiring inductance (Lp). The voltage and current ring after turn-off until settling at time t4, e.g. 28 μs at respectively 600V and 0 A, respectively. The voltage rings at T_{OFF} due to high dI/dt ringing in the current waveform and parasitic wiring inductance. Such ringing may generate excessive conducted and radiated emissions that can affect the system control circuitry or cause a power device failure in a HPDPM. The waveforms of FIG. 3. illustrate an undesirable mode of circuit operation that must be mitigated before the HPDPM can be used in a power system.

The saturable reactor 150 may be included in the circuit′ 00, specifically in series with the switches 210B to limit the peak current through the switches 210B as they turn on into the parasitic capacitance (Cp) of the circuit 200 resulting from the switches 210A and the diodes 220A, The inductance of the saturable reactor 150 changes from a large to a small value (in the saturated core state) to a large value (in the unsaturated core state) once the core resets itself about the zero current level. The large inductance of the saturable reactor in the unsaturated core state reduces the dI/dt in the circuit 200 to a very low value and forces the ringing (having a very high peak current) in the switches 210B to stop.

The voltage-time (VS) product of the saturable reactor 150 may be desirably increased (extended) to limit such peak circuit current. The extended VS product allows the saturable reactor 150 to maintain its maximum inductance for a longer duration. Extending the V-S product may increase the characteristic impedance of the circuit 200, which limits the T_{ON} spike of current through the switches 210B.

The characteristic impedance (Zo) and peak current (Ip) are defined in Equations (5) and (6).

$$\begin{matrix} Zo = √ ( ( ( Lp + Lsr ) ) / Cp ) = 12 Ω & ( 5 ) \\ Ip = \frac{( Vin )}{( Rdson + Zo )} = ( ( 600 V ) ) / ( ( 0.015 Ω + √ ( ( 50 nH + 1.2 uH ) / Cp ) ) = 50 A & ( 6 )\end{matrix}$$

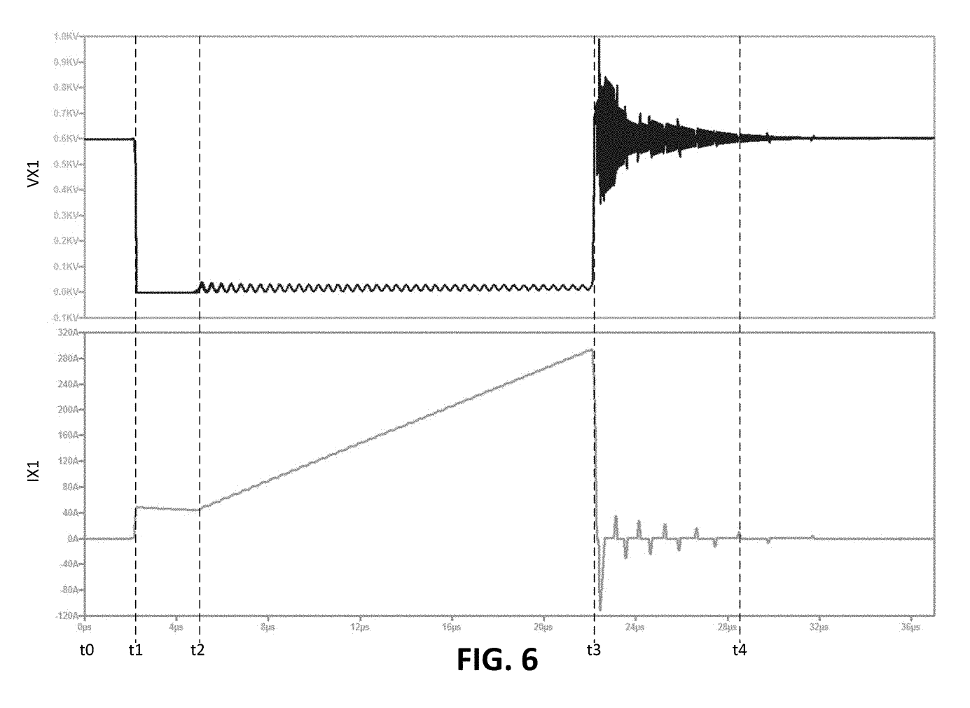

### Let: Ip=50 A, Vin=600V, Lp=50 nH, Cp=8.79 nF, Rdson=0.015Ω, Lsr=1.2 uH (SR LMax)

Where: Lsr=inductance of saturable reactor 150
The amplitude of the calculated peak turn on current (Ip) of 50 A is illustrated in FIG. 6-IX1.
This reduces the T_{ON} spike of current by a factor of 5 (250 A/45 A)=5.56.

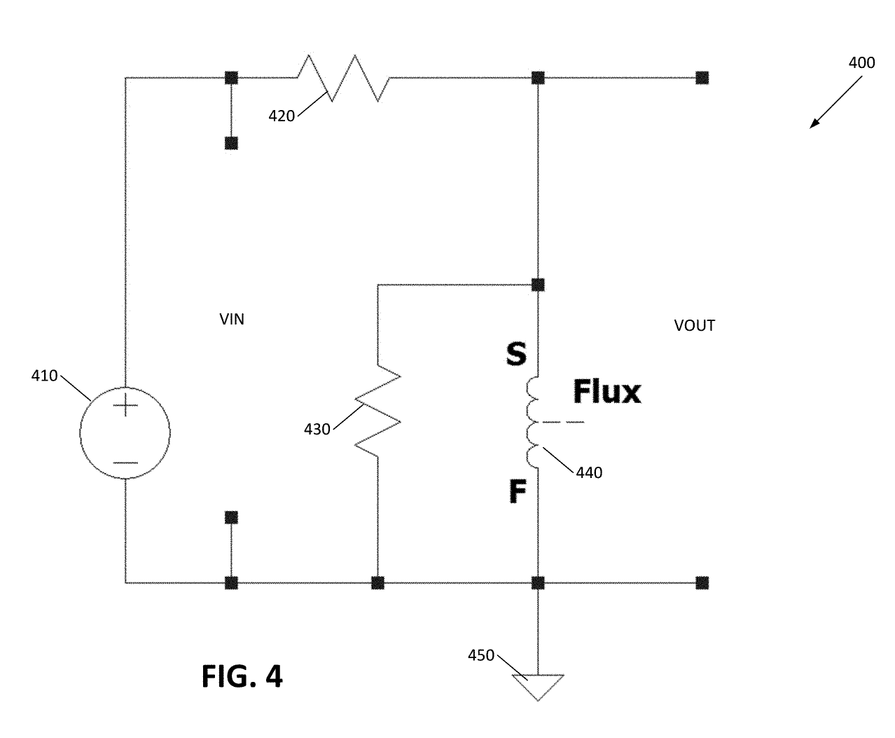

FIG. 4 illustrates a circuit, generally designated as 400, for testing a saturable reactor model, in accordance with an exemplary embodiment of the invention. The circuit 400 comprises a voltage source 410 connected in series to a first resistor 420, which is connected in series with a second resistor 430 and a saturable reactor 440. The second resistor 430, representing core loss of the saturable reactor, and the saturable reactor 440 are connected in parallel. The voltage source 410, the second resistor 430, and the saturable reactor 440 are all also connected to ground 450.

The circuit 400 demonstrates the Volt-Second (V-S) capability of the model of the saturable reactor used in the circuit simulation 200′. The resistors 420 and 430 form an impedance divider, with the leg formed from the resistor 430 in parallel with the saturable reactor 440.

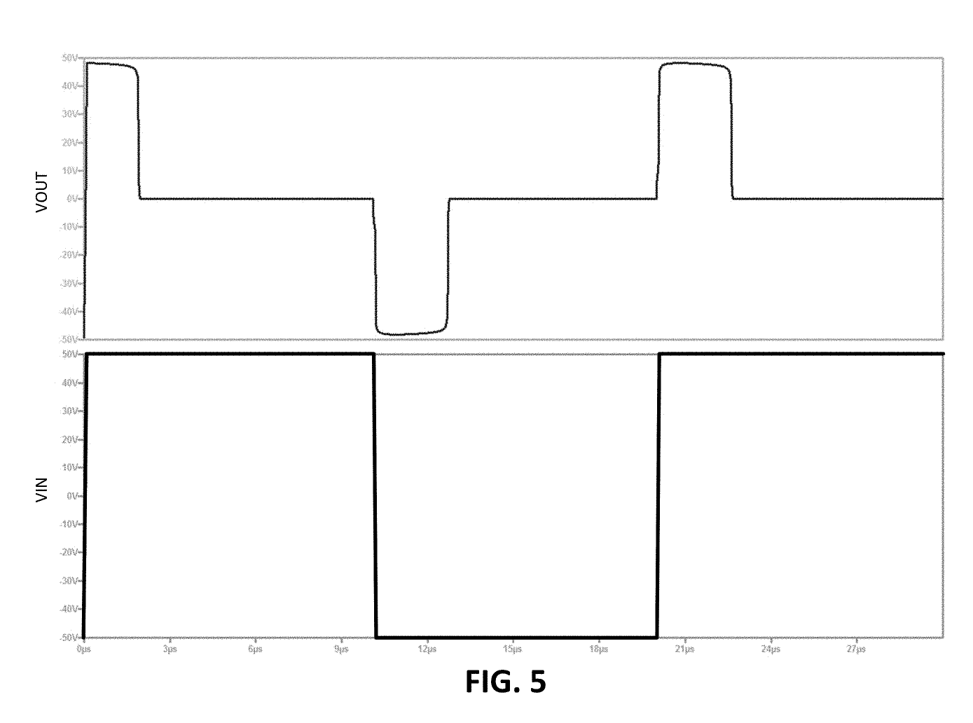

FIG. 5 illustrates waveforms resulting from a PSPICE simulation of the circuit 400, in accordance with an exemplary embodiment of the invention. In such simulation, the resistor 420 was simulated as a 100Ω resistor; the resistor 430 was simulated as a 10k Ω resistor.

During the simulation, the voltage source 410 applied a 500VμS square wave input (VIN) illustrated in FIG. 5. Before the saturable reactor 440 saturated at about 3 μS, it appeared to the source 410 as a very high impedance. Thus, between 0 μS and <3 μS, VOUT=VIN.

The output of the test circuit 400, VOUT, illustrated in FIG. 5, shows the core of the saturable reactor 440 saturating after 50V is applied for 3 μS, at which time the saturable reactor 440 appeared to the source 410 as a very low impedance, much lower than the resistor 420. Thus, after 3 μS, VOUT=0V, i.e., it shorted to the ground 450. FIG. 5 thus demonstrates the 150VμS (50V for 3 μS) capability of the saturable reactor 440 and also that the saturable reactor 440 acts as a low impedance V-S controlled switch.

Referring now to FIG. 6, there are illustrated voltage and current waveforms of the switches 210B for an embodiment of the circuit 200 in which the saturable reactor 150 has been inserted in the circuit 200, the Voltage Snubber Capacitor 140 is not populated, and simulated as the model 200′ accordingly, in accordance with an exemplary embodiment of the invention. FIG. 6 illustrates the role of the saturable reactor 150 in the circuit 200. Between t0 and t1, e.g. between 0 seconds (s) and 2 μs, the switches 210B are off and, therefore, not conducting. Thus, the voltage across the switches 210B is equal to Vs, e.g. 600V and the current through the switches 210B is 0 A between t0 and t1.

At time t1, the switches 210B are turned on and the voltage decreases to the voltage drop across the switches 210B. The current increases to about 45 A without ringing. The voltage across the switches 210B also does not ring at T_{ON}. The saturable reactor 150 limits the increase in current.

By time t2, e.g. 7 μS, the saturable reactor 150 saturates, thereby lowering its inductance to its minimum inductance value. After time t2, the current increases linearly at the slope of VIN/L2 (e.g. 600V/4 μH) and continues increasing until time t3, e.g. 22 μS, to a peak value of 300 A.

At time t3, e.g. 22 μs, the switches 210B are turned off and the voltage across the switches 210B spikes, e.g. to 1.2 kV, and rings excessively thereafter. At time t3 the current through the switches 210B spikes down, e.g. to −80 A and rings thereafter above and below the zero current reference, albeit at a significantly slower rate than in the embodiment of the circuit 200 lacking the saturable reactor 150 (see FIG. 3).

In the exemplary results shown in FIG. 6, the switches 210B approximately 400V of voltage overshoot and high frequency ringing caused by the reduced dI/dt during T_{OFF} at zero crossing, parasitic capacitance (Cp), and parasitic wiring inductance (Lp). The voltage and current ring after T_{OFF} until settling at time t4, e.g. 32 μs at respectively 600V and 0 A, respectively. The voltage rings at T_{OFF} due to a lower dI/dt ringing in the current waveform and parasitic wiring inductance and capacitance. Such ringing is desirably reduced but high voltage overshoot and high frequency ringing may be reduced still further when a Voltage Snubber Capacitor 140 used in concert with saturable reactor 150.

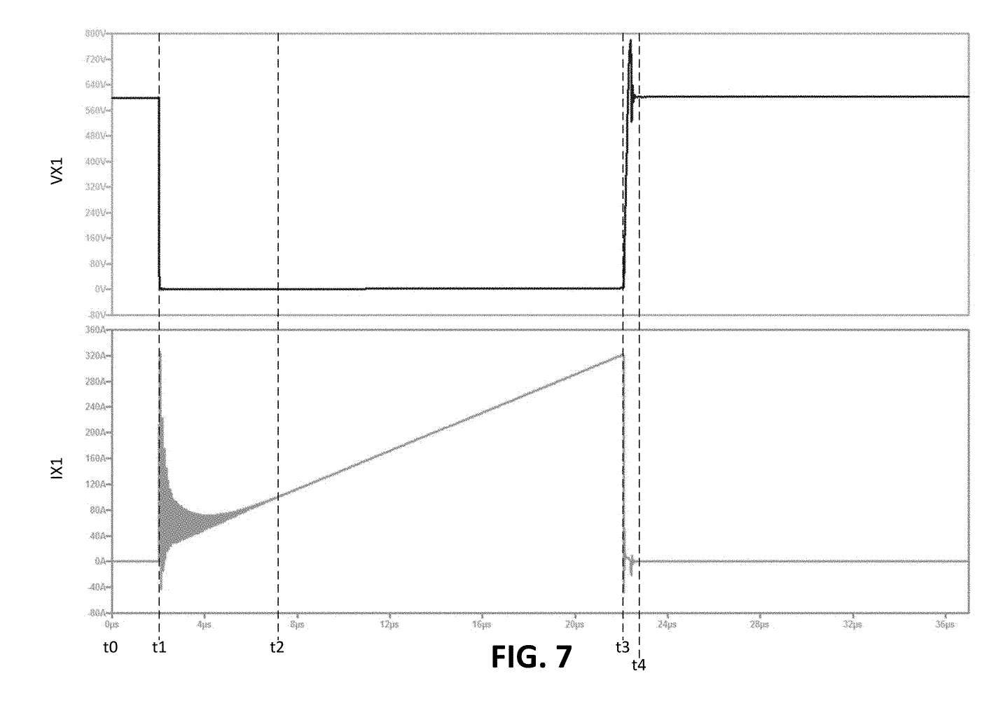

Referring now to FIG. 7, there are illustrated voltage and current waveforms of the switches 210B for an embodiment of the circuit 200 in which the saturable reactor 150 has been removed from the circuit 200, a Voltage Snubber Capacitor 140 is added, and simulated as the model 200′ accordingly, in accordance with an exemplary embodiment of the invention. FIG. 7 illustrates the role of the voltage snubber 140 in the circuit 200. Between t0 and t1, e.g. between 0 s and 2 μs, the switches 210B are off and, therefore, not conducting. Thus, the voltage across the switches 210B is equal to Vs, e.g. 600V, and the current through the switches 210B is 0 A between t0 and t1.

At time t1, the switches 210B are turned on and the voltage decreases to the voltage drop across the switches 210B. The current spikes, e.g. to 320A, and rings excessively at T_{ON}. Specifically, the current spikes above and then below the zero current reference (ground potential) and oscillates or rings between +/−. The voltage across the switches 210B does not ring at T_{ON}. After t1, the current increases linearly, while the excessive ringing eventually subsides by time t2, e.g. 7 μs. The current increases linearly at the slope of Vin/L2 to a peak value of 300 A at time t3, e.g. 22 μs. The peak T_{ON} current is higher in FIG. 7 compared to FIG. 6 because of absence of the saturable reactor 150. The amplitude of voltage overshoot and high frequency ringing is significantly reduce, as shown in FIG. 7, between the time interval t3 and t4.

At time t3, e.g. 22 μs, the switches 210B are turned off and the voltage across the switches 210B spikes mildly, e.g. to 780V, and rings slightly thereafter. At time t3 the current through the switches 210B decreases, e.g. to −40 A and rings mildly thereafter above and below the zero current reference. In the exemplary embodiment shown, the switches 210B sees 780V of voltage overshoot and mildly ringing caused by the Voltage Snubber Capacitor 140 absorbing the energy stored in the parasitic wiring inductance (Lp) and the added “damping” of the parasitic components in the circuit. The voltage and current ring after turn-off until settling at time t4, e.g. 23 μs at respectively 600V and 0 A, respectively. The voltage rings mildly at T_{OFF} due to the value of Voltage Snubber Capacitance, the peak turn off current, and the parasitic wiring inductance but is within acceptable ranges. The voltage ringing overshoot at time t3 in FIG. 7 is less than that of FIG. 6 because the snubber capacitor 244A dampens the parasitic circuit components and absorbs energy stored in the inductance in the wiring (Lwire1, Lsnub).

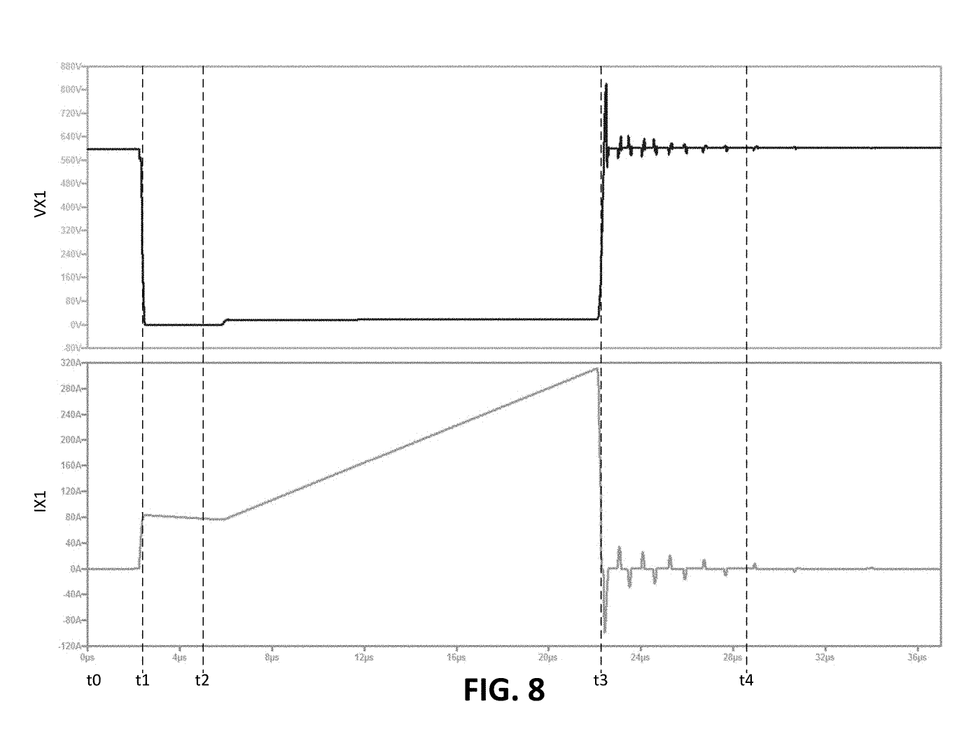

Referring now to FIG. 8, there are illustrated voltage and current waveforms for the circuit 200 that integrates both a saturable reactor 150 and a Voltage Snubber Capacitor 140, in accordance with an exemplary embodiment of the invention. As shown, the peak T_{ON} current and T_{OFF} voltage overshoot are reduced to acceptable operation levels. The ringing in the voltage and current waveforms is also reduced significantly.

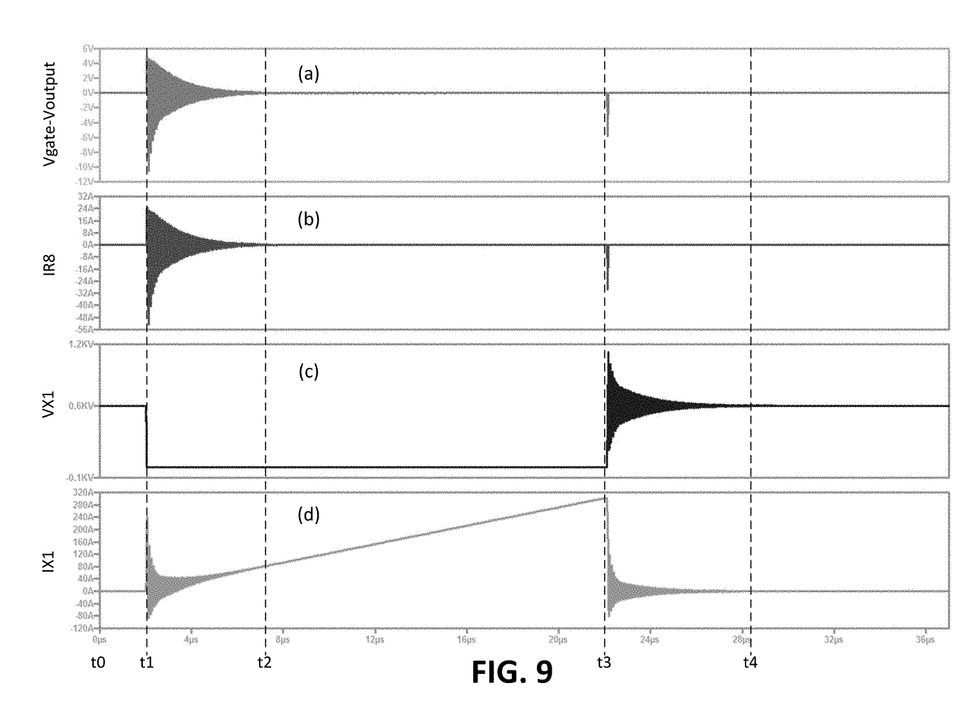

Referring now to FIGS. 9A-D, there are illustrated various voltage and current waveforms resulting from a PSPICE simulation of the circuit 200 without the saturable reactor 150 and without the voltage snubber 140. FIGS. 9C and 9D are the same as FIGS. 3A and 3B, respectively, and are replicated in FIG. 9 for comparison to FIGS. 9A and 9B.

FIG. 9A illustrates the difference in voltage at the gates 210A.3 and at the outputs 210A.2 of the switches 210A. FIG. 9B illustrates the current into the gates 210A.3 of the switches 210A. FIGS. 9A and 9B illustrate significant high-frequency switching noise (HFSN) that is coupled into the gates 210A.3 of the switches 210A during T_{ON} of the switches 210B. Such noise is sufficient to turn-ON and turn-OFF the switches 210A when the switches 210B are turned ON and switches 210A are turned OFF during operation of the H-bridge circuit when a saturable reactor 150 and a voltage snubber 140 are not present in circuit 200.

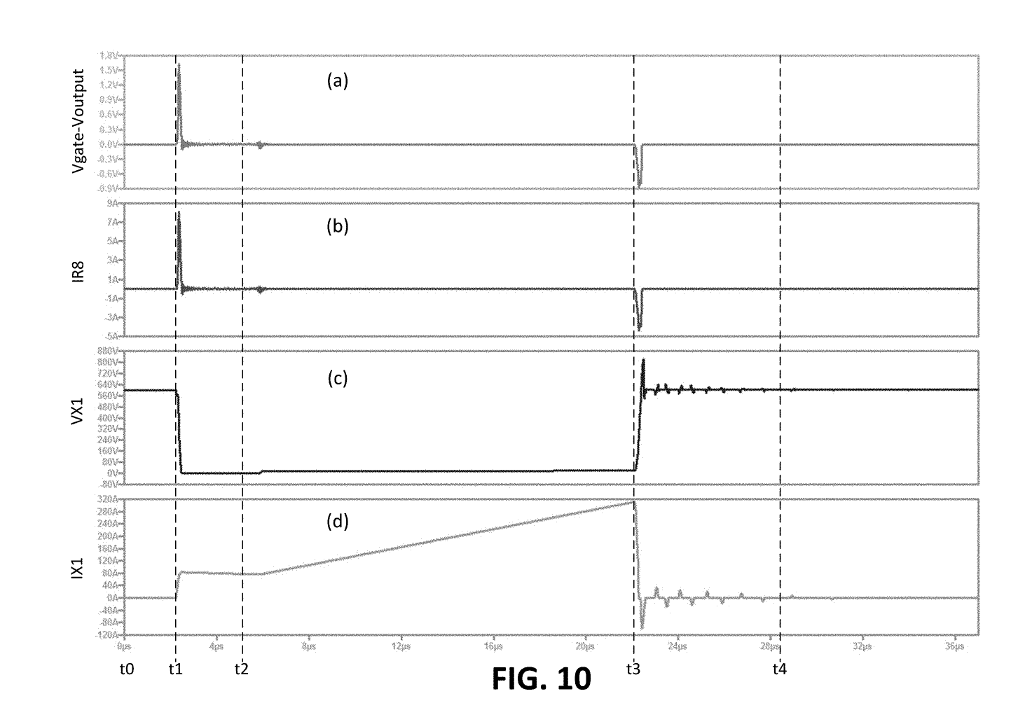

Referring now to FIGS. 10A-D, there are illustrated various voltage and current waveforms resulting from a PSPICE simulation of the circuit 200 with the saturable reactor 150 and the voltage snubber 140. FIGS. 10C and 10D are the same as FIGS. 8A and 8B, respectively, and are replicated in FIG. 10 for comparison to FIGS. 10A and 10B. FIGS. 10A and 10B show that HFSN is significantly reduced into the gates 210A.3 of the switches 210A during T_{ON} of the switches 210B when both the saturable reactor 150 and the voltage snubber 140 are used in the circuit 300

If not controlled, the HFSN can easily couple into the gates 210A.3 of the switches 210A through the drain-to-gate capacitance (Miller capacitance) of the switches 210A, e.g. if they are MOSFETs. False triggering of switches 210A can damage them or create an unstable power system. The results of the PSPICE simulation illustrated in Table 2 below show that a saturable reactor 150 and voltage snubber 140 provide desirable performance for the circuit 200 in reducing excessive voltage overshoot and high-frequency switching noise. This is visually verified in the PSPICE waveforms shown in FIGS. 10A-D.

TABLE 2
Circuit 200 configuration and HFSN comparison

| | | | | Turn | | | | |
|---|---|---|---|---|---|---|---|---|
| | Noise | ETSR | Snubber | ON | Turn | Turn | Excessive | HFSN |
| | Suppression | 150 | Capacitor | Current | ON | OFF | Voltage Over | In |
| FIG. | Configuration | used? | 140 used? | Spike? | Noise? | Noise? | Shoot? | Gate? |
| 3 | 1 | No | No | Yes | Yes | Yes | Yes | Yes |
| 6 | 2 | Yes | No | No | No | Yes | Yes | Yes |
| 7 | 3 | No | Yes | Yes | Yes | No | No | Yes |
| 8 | 4 | Yes | Yes | No | No | No | No | No |

The withstand area product formula, given in Equation (7) below, defines the design variables and the V-S capability of the ETSR 150. FIG. 5 shows the voltage-time waveforms of the simulated core, used in the circuit model 200′, saturating at 150 VuS. An ERSR 150 was reduced to practice using a tape wound core (distributed air gap) with a maximum ΔB of 5700 G. A suitable core volume was selected and Equation (7) was rearranged to solve for the number of turns to obtain a withstand area product of 150 VuS.

(V)(S)=(ΔB)(Ac)(N)( [symbol] 10 [symbol] ^{↑(-θ))} (7)
Where:
V=Volts (V)
S=Time (Sec)
ΔB=Change in Flux (Gauss)
Ac=Core Area (cm²)
N=Number of Turns (Turns)

The ETSR 150 can be designed with or without a discrete air gap. Exemplary materials that may be used for the distributed air gap type core material include Magnetics Molypermalloy Powder (MPP) cores made from a 79% Nickel, 17% Iron, and 4% Molybdenum alloy powder or Magnetics Kool Mu cores made from a 85% Iron, 9% Silicon, and 6% Aluminum alloy powder (Kool Mu) to help reset the core to its minimum residual flux (Br) value to avoid premature saturation. Tape wound cores that are manufactured with Finemet FT3 (Bsat=12,300 G) are a desirable choice to reduce the volume of the saturable reactor design by using high flux material. Cobalt-based amorphous alloys (e.g. 2714A from Metglas) (5700 G) has a lower maximum flux and operating temperature but has low core losses and can run at high frequencies. Both Finemet and cobalt-based amorphous alloy cores have many positive attributes such as high saturation flux, low core loss, high operation temperature (225 C-570 C), and “square” to “tilted” BH curves. The size and weight of the ETSR 150 can be reduced using higher flux levels at the tradeoff core loss.

In an embodiment, the HPDPM circuit 200 may be configured as an energy return power converter circuit that can include a forward converter or a flyback converter. The energy return circuit may be, in embodiments, one of two types power converters that may be integrated into circuit 200 to use the stored parasitic energy in the snubber capacitor: Forward Converter and a Fly back converter.

FIG. 11A illustrates an energy return circuit, generally designated as 1100 that may be configured as a power converter circuit for returning parasitic energy from the circuit to an external load using a forward converter topology, in accordance with an embodiment of the invention. In an embodiment, the energy return circuit 1100 may be integrated with HPDPM circuit 200 of FIG. 2 to return parasitic energy stored in a voltage snubber capacitor 244A (FIG. 2) to the voltage rail OUT1 and to local energy storage capacitor 205B, or to power a secondary or an external power supply connected to circuits that normally requires a second power converter.

As illustrated in FIG. 11A, energy return circuit 1100 may be configured as a forward mode power converter that may return parasitic energy from snubber capacitor 1104 to the voltage rail 1106 when the module power switch 1102 turns ON. Various components of the circuit 200 may be included in the circuit of FIG. 11A, specifically the switch 1102 (similar to the switch 210B), the PVS 1103 including a voltage snubber capacitor 1104 and a schottky diode 1105 (similar to the PVS140). The energy return circuit 1100 includes a module power switch 1102, such as a JFET that includes drain, gate and source nodes, a PVS circuit 1103 including Diode 1105 and snubber capacitor 1104, and a transformer 1108. Also illustrated in FIG. 11A, circuit 1100 includes an isolated transformer 1108, a PVS circuit 1103, and an energy storage capacitor 1110.

The transformer 1108 is connected to the snubber capacitor 1104 to receive its energy and transfer the energy to the voltage rail 1116, through steering diode (dclamp1), when the module power switch turns ON. The transformer may be manufactured using a bifilar winding geometry to reduce leakage inductance (Lleakage1) and to reduce AC wire power loss. The transformer 1108 comprises primary windings and secondary windings. The primary windings are connected to the PVS 1103 and the secondary windings are connected to the energy storage capacitor 1110 through Diode 1111. The wire resistances (Rprim_1, Rprim_2, RS1, and RS2) in the primary and the secondary windings (LP1, LP2, LS1, LS2) are modeled in series with their associated magnetizing inductance. The primary turns of the transformer are wired in parallel and the secondary turns are wired in series. The resonant inductor (Lres) wired in series with the secondary winding of the transformer has a significant effect on the amplitude of resonant discharge current and discharge time.

Circuit 1100 includes a body diode 1112 across switch 1102. In an example, the body diode 1112 and switch 1102 may be a 10 milliohm (mΩ) MOSFET. The PVS 1103 limits the dV/dt across the power switch 1102. The snubber capacitor 1104 may capture energy from the wiring inductance and the leakage inductance of the ETSR 150 (FIG. 2) in the circuit 200 (FIG. 2). The transformer 1108 may use a turn's ratio of 2 to ensure the output voltage on voltage rail 1106 is much higher than the amplitude of the clamp voltage 1114. The transformer 1108 may be manufactured using a bifilar winding geometry to reduce leakage inductance (Lleakage1) and to reduce AC wire power loss. The circuit 1100 further comprises various components that model parasitics such as, for example, resistors Rprim_1, Rprim_2, Leakage1, RS2, RS1 RSnub2, Csnub2 and Lres1. The resistors Rprim_1, Rprim_2, RS2 and RS1 model core losses of the transformer as resistance. The inductor Lleakage1 represents the leakage inductance of the transformer 1108. The wire resistances (Rprim_1, Rprim_2, RS2, RS1) in the primary and the secondary windings of transformer 1108 are modeled in series with their associated magnetizing inductance.

Exemplary values of the various components in the circuit of FIG. 11A are shown in Table 3 below:

TABLE 3
Value of components used in the simulation
of the circuit model 1100

| Component | Value | |
|---|---|---|
| N | 2 | |
| C1 (1104) | 0.22 | uF |
| Voltage Load (1116) | 600 | V |
| L_{leakage1} | 0.1 | uH |
| LP2 | 0.816 | mH |
| LP1 | 0.816 | mH |
| LS1 | 0.816 | mH |
| LS2 | 0.816 | mH |
| R5 | 28 | mΩ |
| R6 | 28 | mΩ |
| R7 | 28 | mΩ |
| R8 | 28 | mΩ |
| Lres1 | 4.8 | μH |
| RSnub2 | 470 | MΩ |
| CSnub2 | 100 | pF |
| C2 (1110) | 100 | μF |

The snubber capacitor 1104 may be the voltage snubber capacitor 244A (FIG. 2) and the value of a snubber capacitor 1104 may be larger than conventional voltage snubbers to capture the energy of both the wiring inductance in the module and the parasitic inductance of the saturable reactor such as, for example, ETSR 150 in FIG. 2. The snubber capacitor 1104 absorbs (catches) the energy from the magnetic component and limits the voltage over shoot to a safe level. The effect of the magnetic component reappears in a positive way at or near zero-current crossing to remove (i.e., to snub) the current oscillation that causes unwanted EMI. The size of the snubber capacitor 1104 may be 0.22 microFarads (μF), which reduces the effect of the energy released from the magnetic components. Returning the energy stored in the snubber capacitor 1104 may gain system efficiency or to power internal or external circuitry that may be external to the circuit 200.

In operation, the energy may be returned to the power rail 1116 by controlling switch 1102 to turn ON the switch and discharge capacitor 1104 into transformer 1108 and transfer power to local energy capacitor 1110. The energy stored in conventional snubber capacitors would normally be wasted energy (dissipated in a discharge resistor) if it not returned to an external power supply or used in another useful way. However, in embodiments described herein, the isolated transformer 1108 may be used to return the stored PVS capacitor 1104 energy to an external power supply at the load 1116 efficiently with a resonant pulse of current through rectifier diode (Dclamp1) 1111. The energy from the PVS capacitor 1104 can be discharged through transformer 1108 into a rectified filter capacitor 1110 that is not connected to the input power system, where a linear regulator or Switch Mode Power Supply (SMPS) can condition the voltage amplitude on the energy storage capacitor 1110 to run electrical active (housekeeping power supplies) or passive (heaters) system circuitry at different ground references. The circuit 1100 provides a solution that has advantages over conventional circuits in that it returns the energy from parasitic magnetic components in circuit 1100 and circuit 200 (FIG. 2) to power circuits and loads that may normally require a second power converter. In conventional circuits. The parasitic energy is wasted energy that may be dissipated into a discharge resistor.

FIG. 11B illustrates an energy return circuit for a power converter, generally designated as 1150 that may be configured with a flyback converter for returning parasitic energy in the circuit to a load using a feedback converter topology, in accordance with an embodiment of the invention. In an embodiment, the energy return circuit 1150 includes a flyback transformer 1502 that may be integrated with HPDPM circuit 200 of FIG. 2 to return parasitic energy stored in a voltage snubber capacitor 244A (FIG. 2) to drive a load connected to a voltage rail 1154 or to power a secondary or external power supply connected to the load for circuits that normally requires a second power converter.

The circuit 1150 of FIG. 11B includes a Polarized Voltage Snubber such as, for example, a PVS 1156 that includes a polarized snubber capacitor C3 and diode D3, an ideal switch S1 with a “steering” diode D2. Circuit 1150 includes a flyback transformer 1152. The isolated flyback transformer 1152, also known as a coupled inductor, includes a primary winding L1_Primary and a secondary winding L1_secondary. The secondary winding is connected to an energy storage capacitor C5. The primary winding is connected to the snubber capacitor_through D2 when M1 is turned on and shorts the finish winding of L1_Primary to ground. The primary windings of the transformer are connected to steering diode D2 and switch M1. The energy return circuit 1150 may use a flyback transformer 1152 to return, the excess energy in snubber capacitor C3 that is captured from magnetic components such as wiring inductances in the circuit 1150 and the parasitic inductances of an ETSR 150 (See FIG. 2) reactor, to a rail or load such as for example, voltage rail 1154.

Circuit 1150 uses an ideal switch S1 to switch an inductive load L1 with a “freewheeling diode (D1). A diode D5 is used to represent an intrinsic body diode connected reverse biased across the drain-to-source of switch S1. In an embodiment, Switch S1 may be a MOSFET or a JFET. A voltage snubber (R4 and C11) is placed across switch S1 to reduce switching transient ringing. A diode (D3) is placed in series with the snubber capacitor (C3) to charge the capacitor (captures parasitic inductive energy) during T_{OFF} and connects the S1-drain to C3. D3 becomes reverse bias when S1 switches on (T_{ON}) and disconnects the charged capacitor C3 from the drain of S1.

In operation, energy is transferred to a polarized voltage snubber capacitor C3 when the switch S1 turns OFF. The voltage snubber capacitor C3 is disconnected from the Drain by reverse biasing D3 when switch S1 turns ON. Energy is transferred from the snubber capacitor C3, through D2, and is stored in the flyback transformer primary windings L1_Primary when the switch M1 is gated ON. Energy is transferred to the clamp capacitor C5 (or load) through the transformer secondary windings L1_Secondary and rectifier diode D4 when the switch M1 turns OFF.

During T_{ON}, the gate signal S1_Gate to switch S1 provides a control signal to both the gate of switch S1 and to the input of a monostable multivibrator (U3A, U3B, R3, and C4). The monostable multivibrator (one shot) generates a positive output pulse to the “SET” input of a NOR gate latch (comprising U1 and U2) on the rising edge of the Gate signal of switch S1. This latches the output of the NOR gate latch U2 to an “ON” state which turns on switch M1. A “Steering diode” (D2) allows C3 to transfer energy into the inductor (L1_primary) by discharging C3 through a parasitic resistance (Rprim) and the external MOSFET switch M1. Energy is transferred to the clamp capacitor C5 (or load) through the transformer secondary L1_secondary and rectifier diodes D4 when the switch M1 turns off. A snubber-capacitor voltage sensing circuit includes an optically-coupled logic gate (for example, a HCPL-2201 from Avago Technologies), Diode D6, Resistor R11, and Vbias_Supply 70 may reset the NOR gate latch when the capacitor C3 voltage is near or at 0V. This resets the snubber capacitor C3 and may allow M1 to turn off at the peak discharge current. Vbias_Supply is adjusted to compensate for the propagation delays from the one shot and NOR gate latch.

FIG. 11C illustrates an energy return circuit for a power converter 1160, generally designated as 1160, in accordance with another embodiment of the invention. The power converter 1160 includes a forward transformer 1162 that may be used with a HPDPM circuit 200 (FIG. 2) to use the energy from a snubber capacitor to run external circuitry, in accordance with another embodiment of the invention. The power converter 1160 may replace a secondary or external power supply that may be external to the HPDPM to run control circuitry

In an embodiment, the energy return circuit 1160 includes a forward transformer 1162 that may be integrated with HPDPM circuit 200 of FIG. 2 to transfer the parasitic energy stored in a voltage snubber capacitor 1164 from the primary windings to the secondary windings of the transformer 1162 and to external circuitry 1170. Similar to the circuit of FIG. 11A, the circuit 1160 of FIG. 11C may include a Polarized Voltage Snubber such as, for example, a PVS 1166 that includes a snubber capacitor 1164 and diode D5. The transformer 1162 is connected to the snubber capacitor 1164 to receive its energy and transfer the energy to the secondary windings 1168, 1171 when the module power switch M2 turns ON. In an embodiment, the isolated bias supply circuit 1170 may adjust the turns ratio for the secondary windings 1168, 1171, to generate various voltage levels with rectifier diodes D7, D8 and filter capacitors C9 and C7. A low drop-out regulator 1172, 1174 may be used to regulate the output from the filter capacitors C7 and C9. In operation, energy is transferred from a polarized voltage snubber capacitor 1164 to the forward transformer primary windings LP1 when the switch M2 turns ON. The energy at the primary windings is transferred to the secondary windings LS1-LS4 when Switch M2 is ON. Energy is transferred to the secondary circuit 1170 that is regulated by regulators 1172, 1174 and to loads at filter capacitors C6-10 and C1-C8.

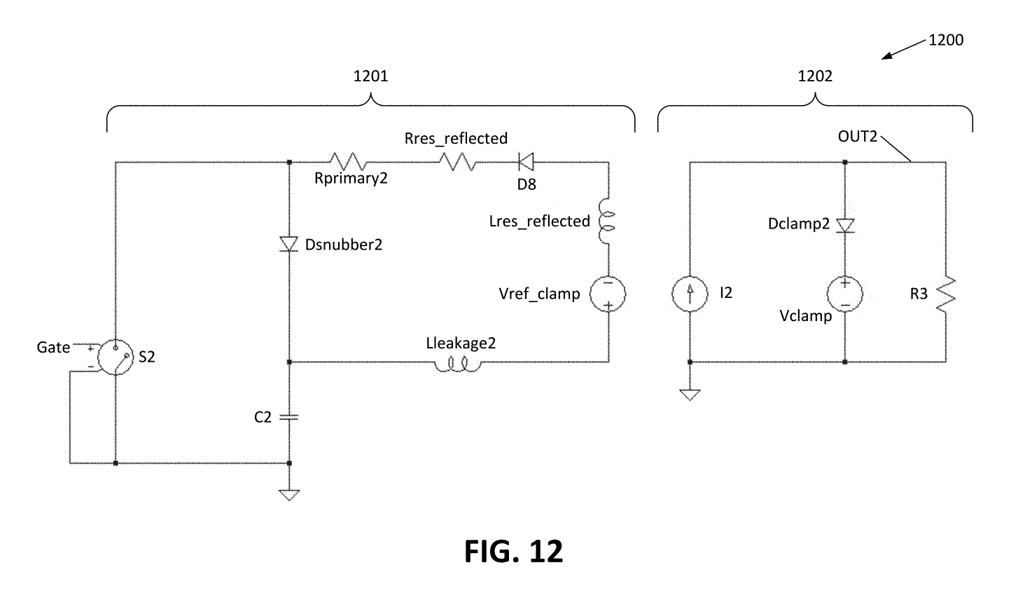

As shown in FIG. 12, with continued reference to FIG. 11A, the value of the inductor Lres1 is reflected back into the primary windings of the isolation transformer 1108 as a function of

$${N}^{2} ( {( \frac{1}{N} )}^{2} )$$

and that the external clamp voltage 1106 (V_{clamp}) is reflected back by

$$\frac{1}{N}$$

times when the second switch 1102 turns on, where N is the ratio of secondary windings to primary windings. The output impedance in the first side 1201 is calculated in Equation (8), the peak discharge current in the secondary windings of the transformer 1108 is calculated in Equation (9), and the discharge time is calculated in Equation (10) below:

$$\begin{matrix} Zo = √ ( ( ( Lleakage + L ( res ) ) ) / C 1 ) = 2.43 Ω & ( 8 ) \\ Is = \frac{IP}{N} = \frac{( V ( C 1 ) - {Vref}_{clamp} )}{( Rdson + Rwire + Zo ) ( N )} = \frac{( 600 V - 287.5 V )}{( 0.038 Ω + \sqrt{\frac{100 n H + 1.2 µ H}{C 1}} ) ( 2 )} = \frac{313}{4.84} = 63 A & ( 9 ) \\ Td = ( π ) √ ( ( Lres , Reflected + Lleakage 2 ) ( C 3 ) ) = 3.14 √ ( 1.2 µ H ) ( 0.22 µ F ) = 1.68 µ S & ( 10 )\end{matrix}$$

As illustrated in FIG. 12, circuit 1200′ functions includes various components that model component values and parasitics that would be present in a reduction to practice of the circuit 1100 of FIG. 11A. Such parasitics include transformer parasitics such as an inductor Lᵣₑₛ_{_}_{reflected}, Vrefclamp, a resistor Rᵣₑₛ_{_}_{reflected}, a resistor Rₚᵣᵢₘₐᵣ, a diode D8 and inductor L_{leakage2}. A PVS is represented as diode D_{snubber2} and capacitor C2. Circuit 1200 comprises a resistor R3 across the series V_{clamp}-D_{clamp2} that represents a load on the output of the circuit 1200.

The values of the various simulated components in the circuit model 1200 are shown in Table 4 below:

TABLE 4
Value of components used in the simulation
of the circuit model 1200′

| Component | Value | |
|---|---|---|
| N | 2 | |
| C2 | 0.22 | uF |
| V(C2) | 600 | V |
| L_{leakage2} | 0.1 | uH |
| V_{ref}_{_{—}}_{clamp} = V_{clamp}/N | 287.5 | V |
| Lᵣₑₛ_{_{—}}_{reflected} | 1.2 | μH |
| R(S2) | 0.010 | Ω |
| Rᵣₑₛ_{_{—}}_{reflected} | 14 | mΩ |
| R_{primary2} | 14 | mΩ |
| V_{clamp} | 575 | V |
| R_{wire} = R_{primary2} + Rᵣₑₛ_{_{—}}_{reflected} | 28 | mΩ |
| R3 | 100 | kΩ |

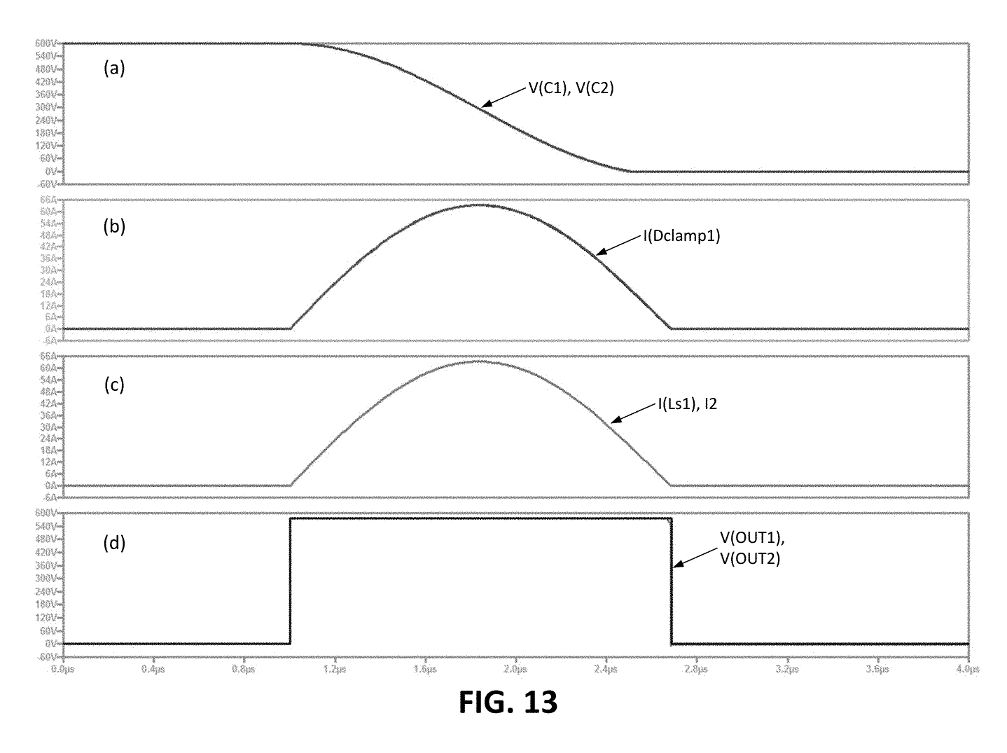

FIGS. 13A-D illustrates various waveforms that depict measurements obtained using forward converter of circuit 1100. FIG. 13A illustrates that the voltages across capacitors C1 (FIG. 11A) and C2 (FIG. 12A) are the same. FIG. 13B illustrates that the currents through Dclamp1 (FIG. 11A) and Dclamp2 (FIG. 12A) are the same. FIG. 13C illustrates that the current through secondary winding LS1 and the current 12 are the same. FIG. 13D illustrates that the voltages at points OUT1 and OUT2 are the same. FIGS. 13A-13D thus illustrate that the circuits 1100′ and 1200′ are the same and that the theory of operation of the circuit 1100′ is correct. The forward converter of circuit 1100 may transfer power when the switch 1102 turns ON. The waveforms illustrate that the snubber capacitor 1104 discharges when the switch 1102 turns ON (shown in FIG. 13A), and current flowing out of the secondary of the transformer 1108 (shown in FIG. 13B-13C)

As described above, the circuit 1100 uses the switches 210B of the circuit 200 to transfer energy from the capacitor 244A to the local energy source capacitor 205B. It is understood that an isolated resonant energy return converter need not use the switches 210B. Rather, an isolated resonant energy return converter could be driven by an external switch instead of using the switches 210B in the circuit 200 in alternative exemplary embodiments. In such alternative exemplary embodiments, the isolated resonant energy return converter may be implemented as either a flyback converter or a forward converter.

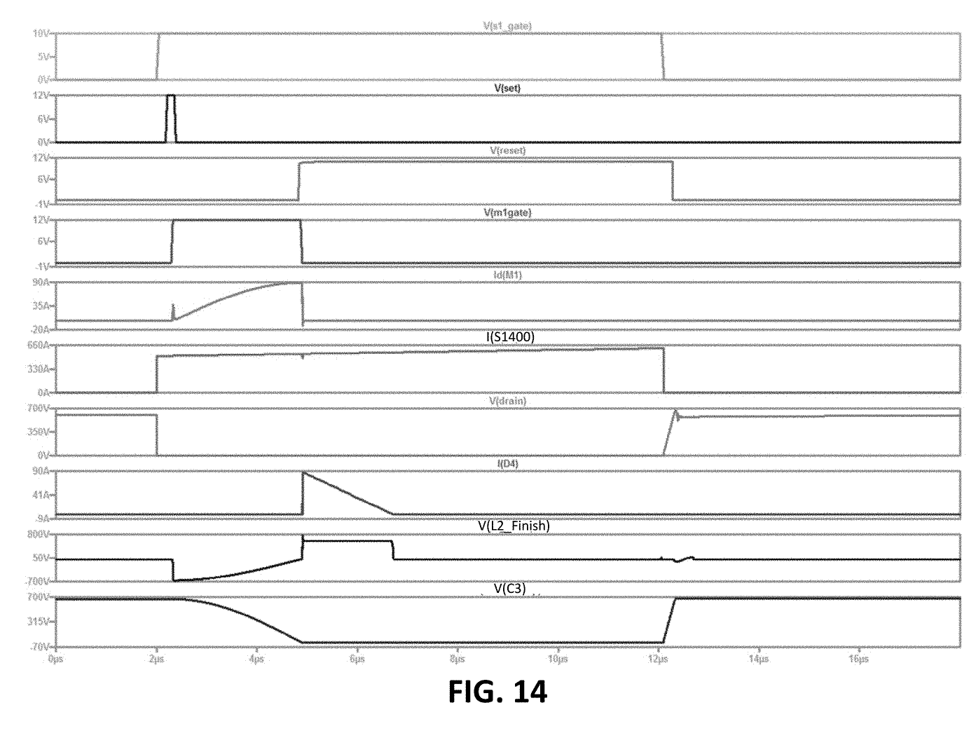

Resonant discharge with constant volt-second balance energy return control circuit waveforms are shown in FIG. 14, in accordance with an exemplary embodiment of the invention. As shown therein, the snubber capacitor C3 discharges through M1, as seen by the decrease in the voltage drop across C3 and the increase in current through M1 between ˜2.5 μs and 5 μs. As the current in M1 increases, the voltage at point L2_finish is negative in polarity. The voltage at L2_finish reverses voltage to a positive polarity after M1 opens and the transformer begins to transfer its energy to the capacitor C5. At around 5 μs, the diode D4 becomes forward biased and starts conducting, as seen in the waveform of I(D4). The energy from the snubber capacitor C3 is then transferred to the capacitor C5. C3 charges to the rail voltage after V(S1_Gate) is gated OFF to complete the cycle of operation.

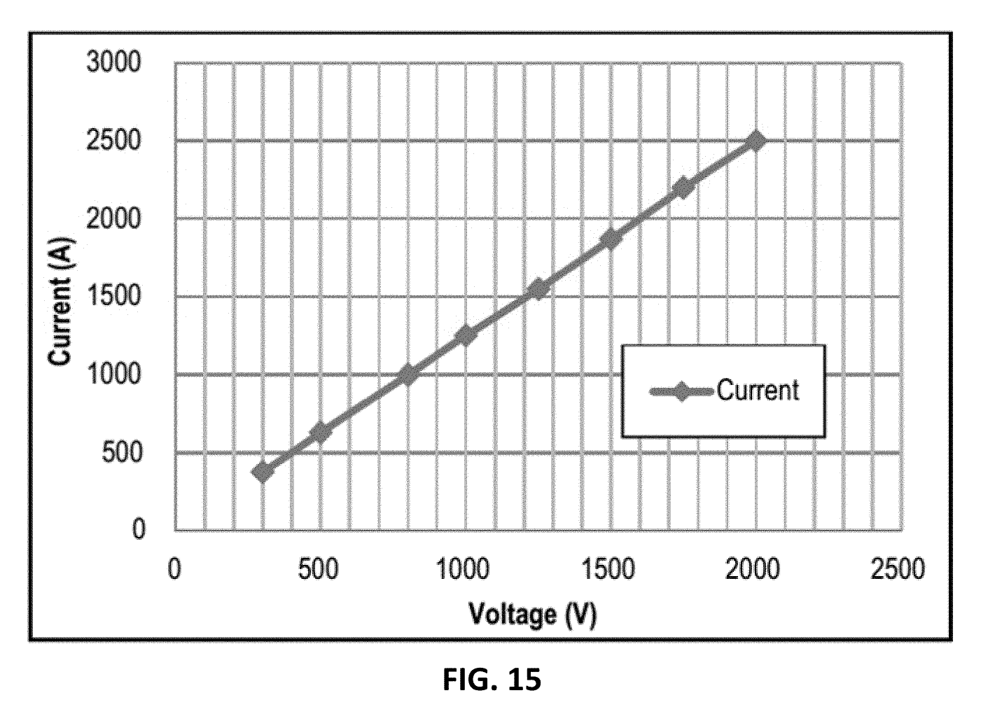

Snubber capacitors should withstand high peak currents because of the high dV/dt across them. Also, the capacitors need to operate at high temperature to function inside a power module. A typical current level for a 0.068 uF capacitor at T_{OFF} is about 1088 A ((0.068 uF)(800V/50 nS)). A Current vs. Voltage curve for a Kemet pulse detonation capacitor is shown in FIG. 15, in accordance with an exemplary embodiment of the invention.

As illustrated in FIG. 15, the peak current requirement was determined by an actual rise time of 55 nS. Current (A)=0.068 uF×(2000V/55 nS)=2473 A;

The capacitor dV/dt rating (maximum voltage slew rate for capacitor in data sheet) is calculated from FIG. 15 with a charging time (charge time) of 55 nS.

dV/dt=I/C=2473 A/0.068e−6F=3.637e10×1e−6=36,367 V/uS
where dV/dt requirement at 2000V calculated from FIG. 15)

dV/dt=I/C=1250 A/0.068e−6 F=1.838e10×1 e−6=18,382 V/uS
where dV/dt requirement at 1000V calculated from FIG. 15)

The circuits 200 and 1100 were reduced to practice and tested at 200 A using a drain-source snubber (the snubber 140) of 68 nF. This snubber lowered the dV/dt enough to eliminate Miller-capacitance-induced failures. The ETSR 150 effectively damped ringing in the both the load and gate circuitry. Voltage overshoot that would have been caused by the intentionally added residual inductance of the ETSR 150 was nearly eliminated with a 68 nF capacitor. This capacitance would have caused power losses of 600 W at 50 kHz, but the energy return circuit 100 reduced the snubber circuit 140 losses to only 34 mW.

Thus in accordance with the invention, a power module is provided that has many high power semiconductor devices and the part count in the module is much higher than a typical power module. The higher than normal power density in the module and the expected increase in efficiency comes from a higher than usual part count of semiconductor devices that are optimized for low conduction and switching energy in the module. The excessive parasitic capacitance and resistances of the devices without countermeasures generates excessive power loss and Electro Magnetic Interference (EMI), which makes the power module unusable and the power system unstable.

The invention includes a magnetic component such as, for example, an extended time saturable reactor (ETSR) to limit peak current when the power module turns on. The effect of the magnetic component disappears after a short length of time, and reappears in a negative way (releasing stored energy) causing voltage overshoot across the power devices when the module switches off. Voltage overshoot may be addressed through a voltage snubber capacitor (VSC). The voltage Snubber Capacitor absorbs or catches the released energy from the magnetic component and limits the voltage over shoot to a safe level. The effect of the magnetic component reappears in a positive way at or near 0 current crossing to remove (snub) the current oscillation that causes unwanted EMI. The size of the VSC may need to be much larger than a typical voltage snubber to reduce the effect of the energy released be the magnetic component. The oversized VSC may charge to the applied voltage during normal switching operation creating a problem of excessive energy on the VSC due to a larger than normal capacitance and voltage. The energy stored in the snubber capacitor is returned to the power sources to gain system efficiency or to power internal or external circuitry.

Two topologies of power converters (Either Forward or Flyback version) are designed internally from the added components used to utilize the potentially lost energy produced by the countermeasures required to make the power module usable and with higher power density normally found in power modules.

The following examples pertain to further embodiments:

Example 1 is a circuit for returning parasitic energy, comprising a first array of semiconductor switches connected in parallel with one another; a second array of semiconductor switches connected in parallel with one another, wherein the second array of semiconductor switches is connected in series with the first array of semiconductor switches; an external load connected in parallel with the second array of semiconductor switches; an energy return circuit including a snubber capacitor, the energy return circuit coupled in parallel with the second array of semiconductor switches; wherein the energy return circuit is configured to transfer parasitic energy from the snubber capacitor to the external load.

In Example 2, the circuit of Example 1 can include, wherein the first array of semiconductor switches and the second array of semiconductor switches comprise one of junction field effect transistors in parallel with respective discrete diodes, metal-oxide-semiconductor field-effect transistors with intrinsic body diodes, or a combination thereof.

In Example 3, the circuit of Example 1 can include, wherein the discrete diode is one of a schottky diode or a fast recovery epitaxial diode.

In Example 4, the circuit of Example 1 to 3 can include, wherein the external load is one of a rectified filter capacitor or an external power supply.

In Example 5, the circuit of Example 4 can include, wherein the snubber capacitor is configured to capture parasitic energy from one or more inductors when at least one switch in the first array of semiconductor switches is switched off.

In Example 6, the circuit of Example 5 can include, wherein the energy return circuit further comprises a transformer including primary and secondary windings, wherein the snubber capacitor is configured to discharge through the transformer and transfer the parasitic energy to the external load when at least one switch in the second array of semiconductor switches is switched on.

In Example 7, the circuit of Example 6 can include, wherein the transformer is configured to transfer the parasitic energy from the snubber capacitor to external load when at least one switch in the second array of semiconductor switches in controlled.

In Example 8, the circuit of Example 1 to 7 can include, wherein the energy return circuit further comprises a flyback transformer including primary windings and secondary windings, the external load coupled to the secondary windings of the flyback transformer; a primary switch coupled to the snubber capacitor, wherein the primary switch is configured to transfer parasitic energy to the snubber capacitor when the primary switch is switched off; and a secondary switch coupled to the primary windings of the flyback transformer; wherein the secondary switch is configured to transfer the parasitic energy from the snubber capacitor to the external load when the external switch is switched off.

In Example 9, the circuit of Example 8 can include, wherein the energy return is configured to transfer the parasitic energy from the snubber capacitor to the primary windings when the secondary switch is switched on.

In Example 10, the circuit of Example 8 can include, wherein the energy return circuit further comprises a monostable multivibrator and a NOR gate latch, the monostable multivibrator configured to transmit a positive input to the NOR gate latch and turn the secondary switch on.

In Example 11, the circuit of Example 10 can include, wherein the monostable multivibrator is configured to send a pulse to the NOR gate latch when at least one switch in the second array of semiconductor switches is switched on.

Example 12 is a circuit for capturing parasitic energy, comprising: a first array of semiconductor switches connected in parallel with one another; a second array of semiconductor switches connected in parallel with one another, wherein the second array of semiconductor switches is connected in series with the first array of semiconductor switches; an extended-time saturable reactor (ETSR) coupled in series to the second array of semiconductor switches, the ETSR configured to limit the instantaneous rate of current change for a predetermined volt-seconds; an external load connected in parallel with the second array of semiconductor switches; and an energy return circuit coupled in parallel with the second array of semiconductor switches, wherein the energy return circuit is configured to transfer parasitic energy to the external load.

In Example 13, the circuit of Example 12 can include, wherein the ESTR comprises an alloy core comprising one of a Finemet, cobalt-based amorphous, Molybdenum Permalloy Powder or Sendust alloy core.

In Example 14, the circuit of Example 12 to 13 can include, wherein the energy return circuit comprises a snubber capacitor, wherein the energy return circuit is configured to transfer the parasitic energy from the snubber capacitor to the external load.

In Example 15, the circuit of Example 14 can include, wherein the snubber capacitor is configured to capture parasitic energy from one or more inductors when at least one switch in the first array of semiconductor switches is switched off.

In Example 16, the circuit of Example 14 can include, wherein the energy return circuit further comprises a transformer coupled to the snubber capacitor, wherein the snubber capacitor is configured to discharge through the transformer and transfer the parasitic energy to the external load when at least one switch in the second array of semiconductor switches is switched on.

In Example 17, the circuit of Example 16 can include, wherein the transformer is configured to transfer the parasitic energy from the snubber capacitor to external load when at least one switch in the second array of semiconductor switches in controlled.

In Example 18, the circuit of Example 14 can include, wherein the energy return circuit further comprises: a flyback transformer including primary windings and secondary windings, the external load coupled to the secondary windings of the flyback transformer; a primary switch coupled to the snubber capacitor, wherein the primary switch is configured to transfer parasitic energy to the snubber capacitor when the primary switch is switched off; and a secondary switch coupled to the primary windings of the flyback transformer; wherein the secondary switch is configured to transfer the parasitic energy from the snubber capacitor to the external load when the external switch is switched off.

In Example 19, the circuit of Example 18 can include, wherein the energy return circuit is configured to transfer the parasitic energy from the snubber capacitor to the primary windings when the secondary switch is switched on.

In Example 20, the circuit of Example 12 to 19 can include, wherein the first array of semiconductor switches and the second array of semiconductor switches comprise one of junction field effect transistors in parallel with respective discrete diodes, metal-oxide-semiconductor field-effect transistors with intrinsic body diodes, or a combination thereof.

In Example 21, the circuit of Example 12 to 20 can include, wherein the discrete diode is one of a schottky diode or a fast recovery epitaxial diode.

In Example 22, the circuit of Example 12 to 21 can include, wherein the external load is one of a rectified filter capacitor or an external power supply.

In Example 23, the circuit of Example 12 to 22 can include, wherein the energy return circuit further comprises a monostable multivibrator and a NOR gate latch, the monostable multivibrator configured to transmit a positive input to the NOR gate latch and turn the secondary switch on.

In Example 24, the circuit of Example 23 can include, wherein the monostable multivibrator is configured to send a pulse to the NOR gate latch when at least one switch in the second array of semiconductor switches is switched on.

The foregoing description and drawings should be considered as illustrative only of the principles of the invention. The invention may be configured in a variety of shapes and sizes and is not intended to be limited by the embodiments. Numerous applications of the invention will readily occur to those skilled in the art. Therefore, it is not desired to limit the invention to the specific examples disclosed or the exact construction and operation shown and described. Rather, all suitable modifications and equivalents may be resorted to, falling within the scope of the invention.

What is claimed is:

1. A circuit for returning parasitic energy, comprising:
a first array of semiconductor switches connected in parallel with one another;
a second array of semiconductor switches connected in parallel with one another, wherein the second array of semiconductor switches is connected in series with the first array of semiconductor switches;
an external load connected in parallel with the second array of semiconductor switches;
an energy return circuit including a snubber capacitor, the energy return circuit coupled in parallel with the second array of semiconductor switches;
wherein the energy return circuit is configured to transfer parasitic energy from the snubber capacitor to the external load.

2. The circuit of claim 1, wherein the first array of semiconductor switches and the second array of semiconductor switches comprise one of junction field effect transistors in parallel with respective discrete diodes, metal-oxide-semiconductor field-effect transistors with intrinsic body diodes, or a combination thereof.

3. The circuit of claim 1, wherein the discrete diode is one of a schottky diode or a fast recovery epitaxial diode.

4. The circuit of claim 1, wherein the external load is one of a rectified filter capacitor or an external power supply.

5. The circuit of claim 4, wherein the snubber capacitor is configured to capture parasitic energy from one or more inductors when at least one switch in the first array of semiconductor switches is switched off.

6. The circuit of claim 5, wherein the energy return circuit further comprises a transformer including primary and secondary windings, wherein the snubber capacitor is configured to discharge through the transformer and transfer the parasitic energy to the external load when at least one switch in the second array of semiconductor switches is switched on.

7. The circuit of claim 6, wherein the transformer is configured to transfer the parasitic energy from the snubber capacitor to external load when at least one switch in the second array of semiconductor switches in controlled.

8. The circuit of claim 1, wherein the energy return circuit further comprises:
a flyback transformer including primary windings and secondary windings, the external load coupled to the secondary windings of the flyback transformer;
a primary switch coupled to the snubber capacitor, wherein the primary switch is configured to transfer parasitic energy to the snubber capacitor when the primary switch is switched off; and
a secondary switch coupled to the primary windings of the flyback transformer;
wherein the secondary switch is configured to transfer the parasitic energy from the snubber capacitor to the external load when the external switch is switched off.

9. The circuit of claim 8, wherein the energy return is configured to transfer the parasitic energy from the snubber capacitor to the primary windings when the secondary switch is switched on.

10. The circuit of claim 8, wherein the energy return circuit further comprises a monostable multivibrator and a NOR gate latch, the monostable multivibrator configured to transmit a positive input to the NOR gate latch and turn the secondary switch on.

11. The circuit of claim 10, wherein the monostable multivibrator is configured to send a pulse to the NOR gate latch when at least one switch in the second array of semiconductor switches is switched on.

12. A circuit for capturing parasitic energy, comprising:
a first array of semiconductor switches connected in parallel with one another;
a second array of semiconductor switches connected in parallel with one another, wherein the second array of semiconductor switches is connected in series with the first array of semiconductor switches;
an extended-time saturable reactor (ETSR) coupled in series to the second array of semiconductor switches, the ETSR configured to limit the instantaneous rate of current change for a predetermined volt-seconds;
an external load connected in parallel with the second array of semiconductor switches; and
an energy return circuit coupled in parallel with the second array of semiconductor switches, wherein the energy return circuit is configured to transfer parasitic energy to the external load.

13. The circuit of claim 12, wherein the ESTR comprises an alloy core comprising one of a Finemet, cobalt-based amorphous, Molybdenum Permalloy Powder or Sendust alloy core.

14. The circuit of claim 12, wherein the energy return circuit comprises a snubber capacitor, wherein the energy return circuit is configured to transfer the parasitic energy from the snubber capacitor to the external load.

15. The circuit of claim 14, wherein the snubber capacitor is configured to capture parasitic energy from one or more inductors when at least one switch in the first array of semiconductor switches is switched off.

16. The circuit of claim 14, wherein the energy return circuit further comprises a transformer coupled to the snubber capacitor, wherein the snubber capacitor is configured to discharge through the transformer and transfer the parasitic energy to the external load when at least one switch in the second array of semiconductor switches is switched on.

17. The circuit of claim 16, wherein the transformer is configured to transfer the parasitic energy from the snubber capacitor to external load when at least one switch in the second array of semiconductor switches in controlled.

18. The circuit of claim 14, wherein the energy return circuit further comprises:
a flyback transformer including primary windings and secondary windings, the external load coupled to the secondary windings of the flyback transformer;
a primary switch coupled to the snubber capacitor, wherein the primary switch is configured to transfer parasitic energy to the snubber capacitor when the primary switch is switched off; and
a secondary switch coupled to the primary windings of the flyback transformer;
wherein the secondary switch is configured to transfer the parasitic energy from the snubber capacitor to the external load when the external switch is switched off.

19. The circuit of claim 18, wherein the energy return circuit is configured to transfer the parasitic energy from the snubber capacitor to the primary windings when the secondary switch is switched on.

20. The circuit of claim 12, wherein the first array of semiconductor switches and the second array of semiconductor switches comprise one of junction field effect transistors in parallel with respective discrete diodes, metal-oxide-semiconductor field-effect transistors with intrinsic body diodes, or a combination thereof.

21. The circuit of claim 12, wherein the discrete diode is one of a schottky diode or a fast recovery epitaxial diode.

22. The circuit of claim 12, wherein the external load is one of a rectified filter capacitor or an external power supply.

23. The circuit of claim 12, wherein the energy return circuit further comprises a monostable multivibrator and a NOR gate latch, the monostable multivibrator configured to transmit a positive input to the NOR gate latch and turn the secondary switch on.

24. The circuit of claim 23, wherein the monostable multivibrator is configured to send a pulse to the NOR gate latch when at least one switch in the second array of semiconductor switches is switched on.
